(19) United States
(12) Patent Application Publication
(10) Pub. No.: US 2026/0262448 A1
(43) Pub. Date: Sep. 3, 2026

(54) LIGHT-EMITTING LAYER, LIGHT-EMITTING DEVICE AND DISPLAY APPARATUS

(71) Applicant: BOE Technology Group Co., Ltd., Beijing (CN)

(72) Inventors: Siqi Wang, Beijing (CN); Bowen Lv, Beijing (CN)

(73) Assignee: BOE Technology Group Co., Ltd., Beijing (CN)

(21) Appl. No.: 18/832,005

(22) PCT Filed: Sep. 26, 2023
(86) PCT No.: PCT/CN2023/121766

§ 371 Date: Jul. 22, 2024

(30) Foreign Application Priority Data
Nov. 18, 2022 (CN) 202211446284.8

(51) Int. Cl. H10K 85/60; C09K 11/06; H10K 50/12; H10K 101/20

(52) U.S. Cl. CPC H10K 85/6572; C09K 11/06; H10K 85/615; H10K 85/654; H10K 85/6576; C09K 2211/1007; C09K 2211/1018; H10K 50/12; H10K 2101/20

(57) ABSTRACT

The present application relates to the technical field of display. Provided are a light-emitting layer, a light-emitting device and a display apparatus. The light-emitting layer at least comprises a first thermally activated delayed fluorescent material, wherein the reverse intersystem crossing rate kRISC of the first thermally activated delayed fluorescent material meets kRISC>1.0×10⁴ s⁻¹, the photoluminescence quantum yield PLQY of the first thermally activated delayed fluorescent material in a neat film state meets PLQY≥50%, and the horizontal dipole ratio θ// of the first thermally activated delayed fluorescent material meets θ//>67%. In the light-emitting layer provided in the present application, a first thermally activated delayed fluorescent material is used, such that the luminous efficiency and luminous performance of a light-emitting device using the light-emitting layer are relatively high.

### CROSS REFERENCE TO RELATED APPLICATION

The present application claims the priority of the Chinese patent application 202211446284.8, titled “LIGHT-EMITTING LAYER, LIGHT-EMITTING DEVICE AND DISPLAY APPARATUS” and filed with China National Intellectual Property Administration on Nov. 18, 2022, which is incorporated herein by reference in their entirety.

### TECHNICAL FIELD

The present application relates to the field of display technology, and in particular to a light-emitting layer, a light-emitting device and a display apparatus.

### BACKGROUND

At present, the emission modes of organic light emitting diode (OLED) display devices are divided into phosphorescence and fluorescence. The fluorescent OLED display devices are increasingly widely used due to their excellent characteristics.

However, the traditional organic fluorescent materials produce singlet and triplet excitons in a ratio of 25:75 when excited, 25% of the singlet excitons emit fluorescence when transitioning to the ground state, and 75% of the triplet excitons do not emit light when transitioning to the ground state. Since a high proportion of triplet excitons cannot be used for luminescence, the luminescence efficiency of traditional fluorescence materials is inevitably low, so that the internal quantum efficiency (IQE) of the fluorescence-based OLED display devices may only reach its theoretical limit at most, resulting in low luminescence efficiency and poor luminescence performance of the traditional fluorescence-based OLED display device.

Therefore, there is an urgent need to provide a new OLED display device to solve the above problems.

### SUMMARY

Embodiments of the present application adopt the following technical solutions.

On the one hand, an embodiment of the present application provides a light-emitting layer, comprising at least:
a first thermally activated delayed fluorescent material, wherein a reverse intersystem crossing rate kRISC1 of the first thermally activated delayed fluorescent material satisfies: kRISC1>1.0×10⁴ s⁻¹, a photoluminescence quantum yield PLQY of the first thermally activated delayed fluorescent material in a pure film state satisfies: PLQY≥50%, and a horizontal dipole ratio θ// of the first thennally activated delayed fluorescent material satisfies: θ//>67%.

Optionally, an energy level difference ΔEST1 between a singlet state and a triplet state of the first thermally activated delayed fluorescent material satisfies: ΔEST1≤0.15 eV.

Optionally, a general structure formula of the first thermally activated delayed fluorescent material is:

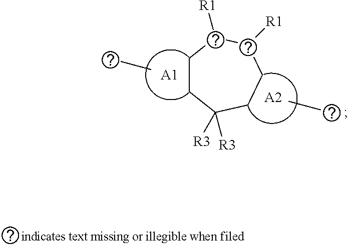

wherein R1-R3 are each independently any one of hydrogen, deuterium, fluorine, chlorine, bromine, iodine, CN, Si(R6)₃, a straight chain alkyl group, an alkoxyl group, a thioalkyl group with 1-40 carbon atoms, a branched chain with 3-40 carbon atoms, a cyclic alkyl group with 3-40 carbon atoms, an alkoxyl group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, and a heteroaralkyl group with 5-60 aromatic rings; R1-R3 may each independently be substituted with one or more R4, R4 is any one of hydrogen, a straight chain alkyl group with 1-22 carbon atoms, an alkoxyl group with 1-22 carbon atoms, a branched chain with 3-22 carbon atoms, a cyclic alkyl group with 3-22 carbon atoms and an alkoxyl group with 3-22 carbon atoms; one or more non-adjacent carbon atoms in R4 may be substituted with any one of oxygen, sulfur, SO, SO₂, CO, O—CO—O, CO—O, —CH═CH— and —C≡C; one or more hydrogen in R4 may be substituted with any one of fluorine, chlorine, bromine, iodine, (CN, an aryl group with 5-40 carbon atoms, a heteroaryl group with 5-40 carbon atoms, an aryloxy group with 5-40 carbon atoms, a heteroatyloxy group with 5-40 carbon atoms, and a non-aromatic group; one or more non-adjacent CH₂ in R1-R3 may each independently be substituted with any one of Si(R6)₂, C═NR6, P(═O)(R6), SO, SO₂, NR6, oxygen, sulfur, and CONR6; and one or more hydrogen atoms in R1-R3 may be substituted with any one of deuterium, fluorine, chlorine, bromine, and iodine;
two or more adjacent R1-R3 form any one of a monocyclic aliphatic ring and polycyclic aliphatic ring, which may be substituted with R4;
at least one of R2 and R3 is not hydrogen;
R1 is substituted with at least one cyano group, R1 contains t nitrogen atoms, and t is any one of 1, 2 and 3;
A1 and A2 are each independently any one of an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, and a heteroaralkyl group with 5.60 aromatic rings, and A1 and A2 may each independently be substituted with one or more R4;
m and n are each independently any one of 0, 1.2, 3 and 4; and
p and q are each independently 0 or 1, and p+q≠0.

Optionally, the first thermally activated delayed fluorescent material comprises diphenylpyridine or nitrogen-containing diphenylpyridine.

Optionally, when the first thermally activated delayed fluorescent material comprises the nitrogen-containing diphenylpyridine, a general structural formula of the first thermally activated delayed fluorescent material is:

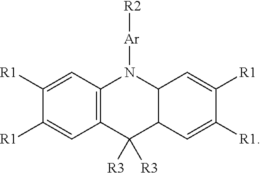

Optionally, R3 is selected from any one of:

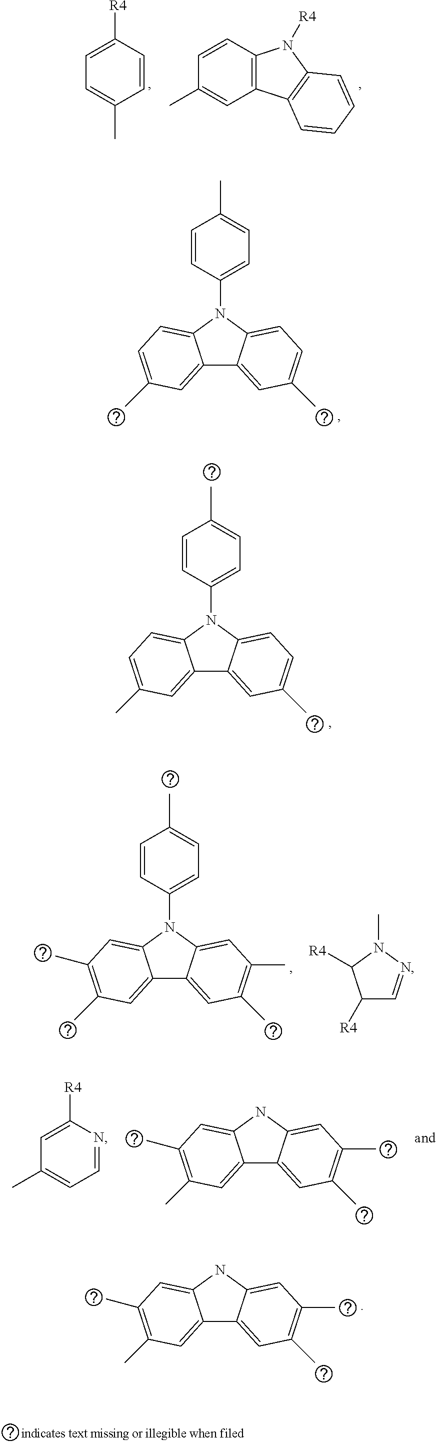

Optionally, a chemical structure formula of the first thermally activated delayed fluorescent material comprises any one of:

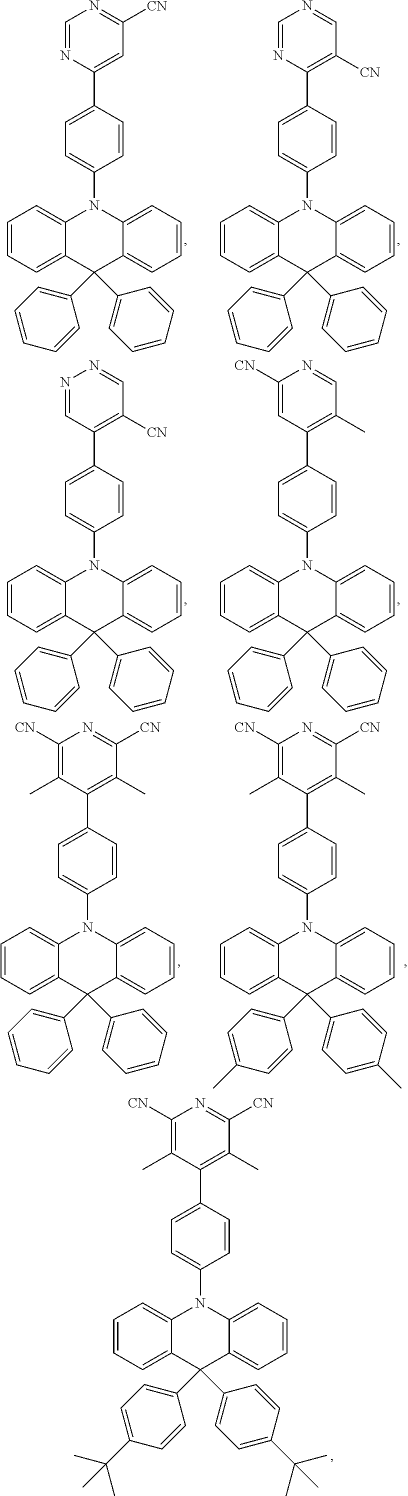

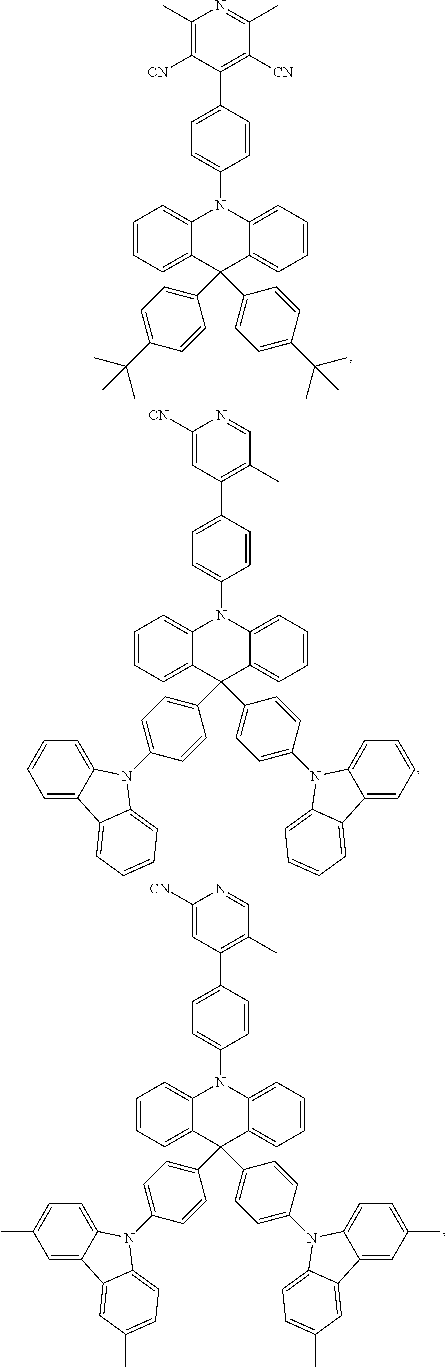

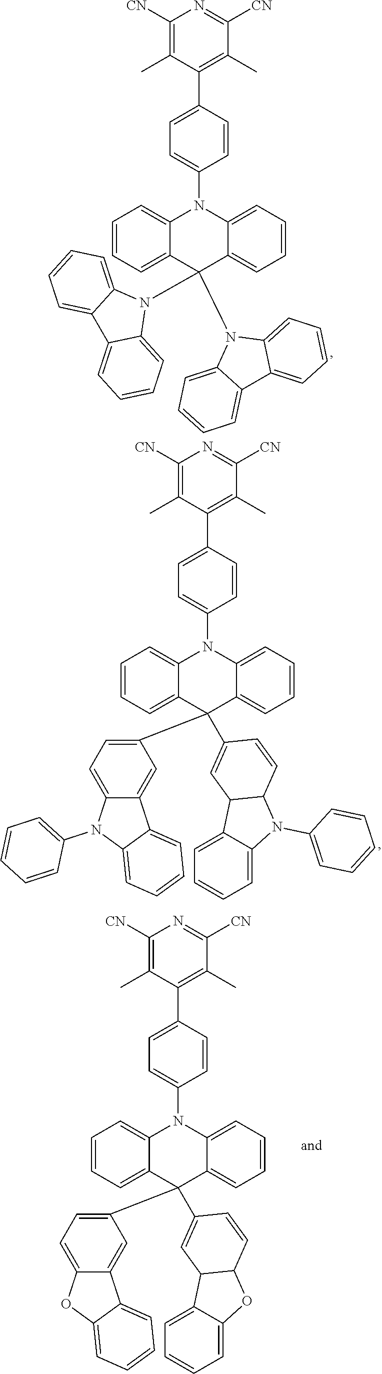

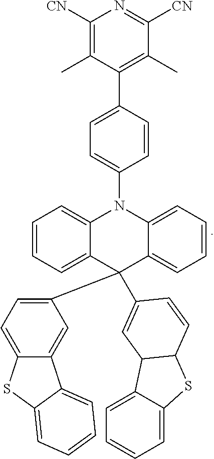

Optionally, the light-emitting layer further comprises a first compound doped in the first thermally activated delayed fluorescent material; and
an absolute value of a difference between reorganization energy λRISC of the first compound and an energy level difference ΔEST2 between a singlet state energy level and a triplet state energy level of the first compound satisfies. |λRISC-ΔEST2|0.1 eV.

Optionally, the first compound is a second thermally activated delayed fluorescent material; and
a reverse intersystem crossing rate kRISC2 of the first compound satisfies: kRISC2>1.0×10⁴ s⁻¹.

Optionally, a general structure formula of the first compound is:

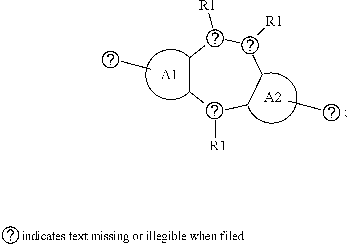

wherein X, Y and Z are each independently any one of carbon, nitrogen, BR3, C(R3)₂, —C(R3)₂—C(R3)₂—, —C(R3)₂—O—, —C(R3)₂—S—, —R3C═CR3-, —R3C═N—, Si(R3)₂, —Si(R3)₂, —Si(R3)₂—, C═O, oxygen, sulfur, S═O, SO₂, NR3, PR3, and P(═O)R3;

R1 is any one of hydrogen, deuterium, fluorine, chlorine, bromine, iodine, CN, Si(R6)₃, a straight chain alkyl group, an alkoxy group, a thioalkyl group with 1-40 carbon atoms, a branched chain alkyl group with 3-40 carbon atoms, a cyclic alkyl group with 3-40 carbon atoms, an alkoxy group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, and a heteroaryloxy group with 5-60 aromatic rings, an aralkyl group with 5-60 aromatic rings, and a heteroaralkyl group with 5-60 aromatic rings; R1 may be substituted with one or more R4. R4 is any one of hydrogen, a straight chain alkyl group with 1-22 carbon atoms, an alkoxy chain with 1-22 carbon atoms, a branched chain with 3-22 carbon atoms, a cyclic alkyl group with 3-22 carbon atoms, and an alkoxy chain with 3-22 carbon atoms; one or more non-adjacent carbon atoms in R4 may be substituted with any one of oxygen, sulfur, SO, SO₂, CO, O—CO—O, CO—O, —CH═CH—, —C≡C; one or more hydrogen atoms in R4 may be substituted with any one of fluorine, chlorine, bromine, iodine, CN, an aryl group with 5-40 carbon atoms, a heteroaryl group with 5-40 carbon atoms, an aryloxy group with 5-40 carbon atoms, a heteroaryloxy group with 5-40 carbon atoms and a non-aromatic group; one or more non-adjacent CH₂ in R1 may be substituted with any one of Si(R6)₂, C═NR6, P(═O)(R6), SO, SO₂, NR6, oxygen, sulfur and CONR6; and one or more hydrogen atoms in R1 may be substituted with any one of deuterium, fluorine, chlorine, bromine and iodine;

two or more adjacent R1 form any one of a monocyclic aliphatic ring and a polycyclic aliphatic ring, which may be substituted with R4;

A1 and A2 are each independently any one of an aromatic ring with 6-60 carbon atoms, a heteroaromatic ring with 6-60 carbon atoms, an aryloxy group with 5-60 aromatic ring, a heteroaryloxy group with 5-60 aromatic rings, an aralkyl group with 5-60 aromatic rings, and a heteroaralkyl group with 5-60 aromatic rings; and A1 and A2 may each independently be substituted with one or more R4;
p, q and t are each independently 0 or 1, and p+q≠0; and
m and n are each independently any one of 0, 1, 2, 3 and 4.

Optionally, the first compound comprises a first electron-donating group, a first electron-accepting group and a first linking group, the first electron-donating group is bonded to the first electron-accepting group through the first linking group, and the first linking group comprises a benzene ring or pyridine.

Optionally, a chemical structural formula of the first compound comprises any one of:

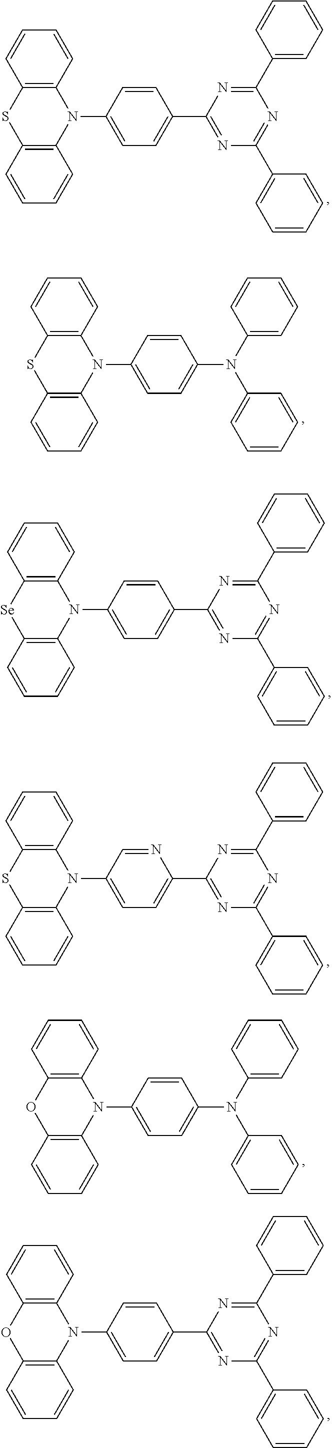

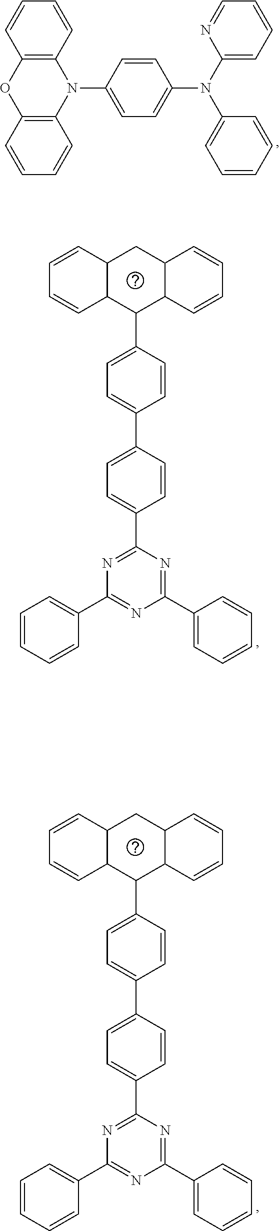 [SMILES: c1ccc(N(c2ccc(N3c4ccccc4Oc4ccccc43)cc2)c2ccccn2)cc1 ; C1=CC2CC3C=CC=CC3C(c3ccc(-c4ccc(-c5nc(-c6ccccc6)nc(-c6ccccc6)n5)cc4)cc3)C2C=C1 ; C1=CC2CC3C=CC=CC3C(c3ccc(-c4ccc(-c5nc(-c6ccccc6)nc(-c6ccccc6)n5)cc4)cc3)C2C=C1]

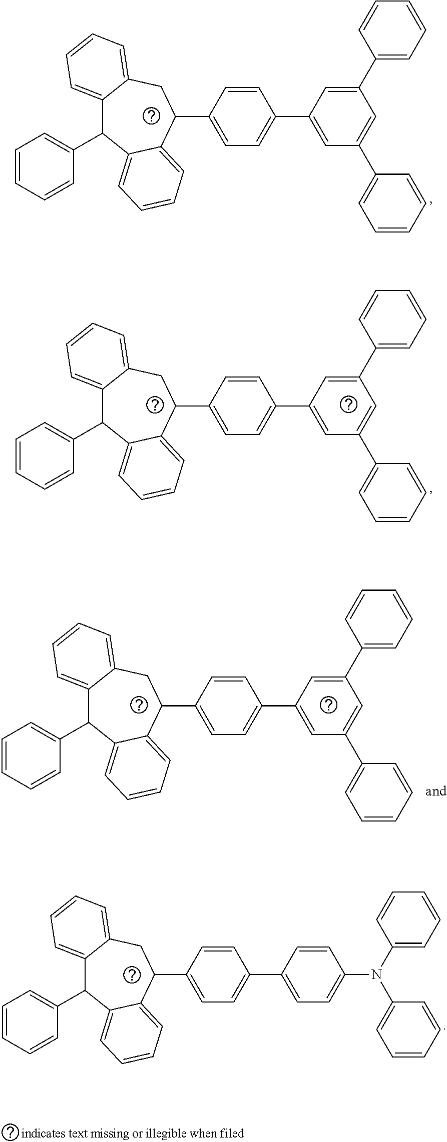

Optionally, the first compound comprises a second electron-donating group, a third electron-donating group and a second electron-accepting group, and the second electron-donating group is bonded to the third electron-donating group through the second electron-accepting group.

Optionally, a chemical structure formula of the first compound comprises any one of:

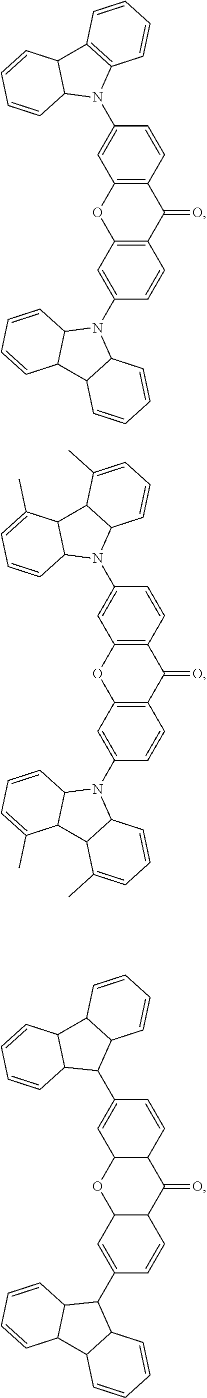

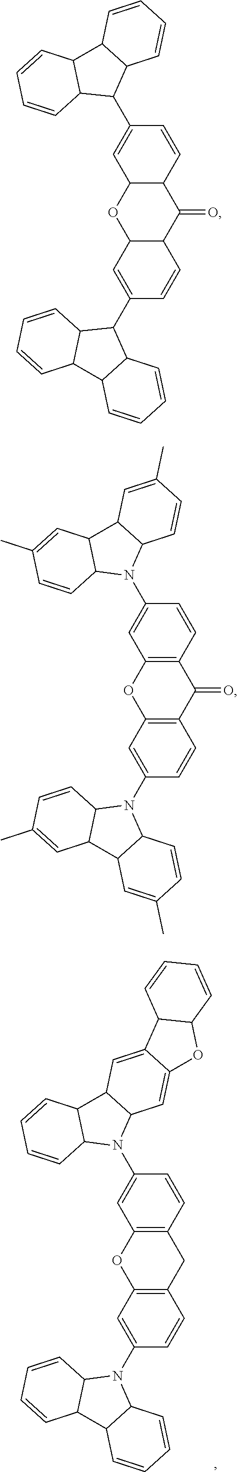

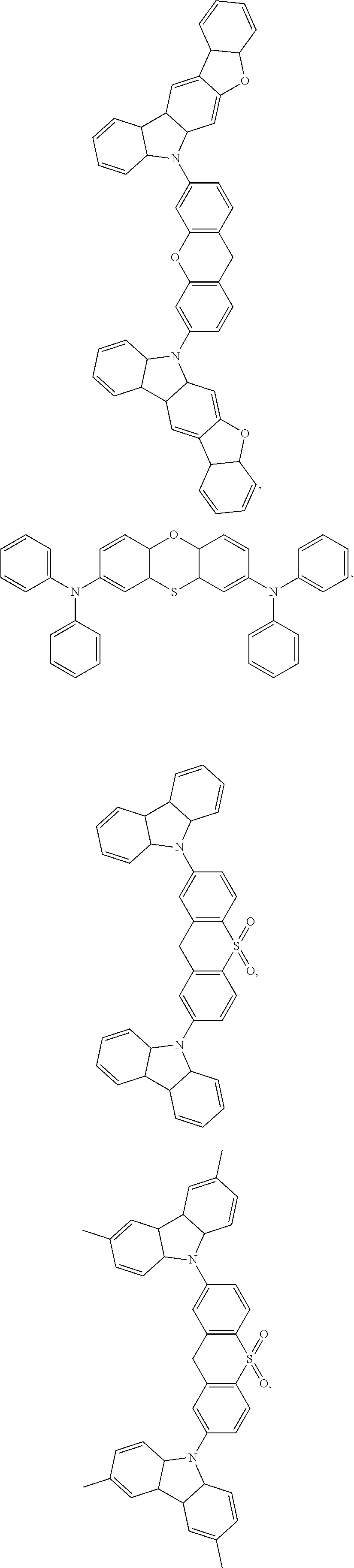

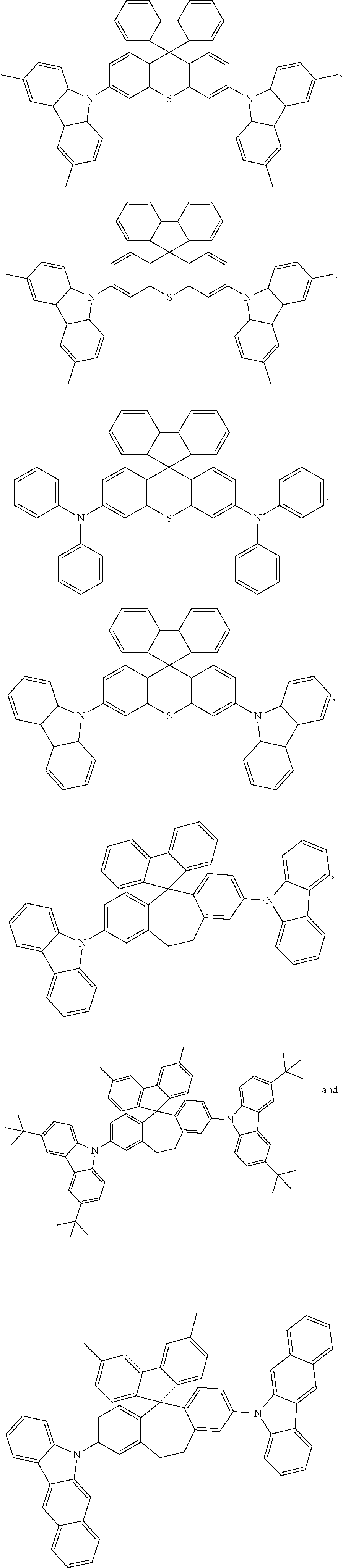

Optionally, the light-emitting layer further comprises a second compound doped in the first thermally activated delayed fluorescent material; and
a triplet state energy level T1 of the first thermally activated delayed fluorescent material satisfies: T1≥2.7 eV.

Optionally, the second compound is a third thermally activated delayed fluorescent material.

Optionally, a general structure formula of the second compound is any one of:

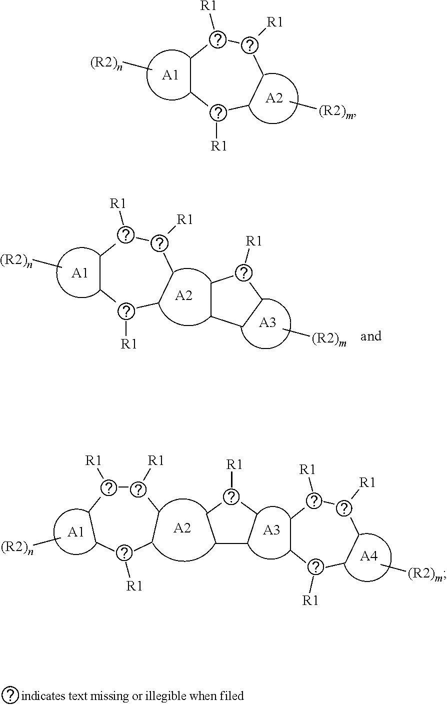

wherein X, Y, Z and W are each independently any one of carbon, nitrogen, boron, oxygen, sulfur, selenium, tellurium, BR₃, C(R3)₂, —C(R3)₂—C(R3)₂—, —C(R3)₂-O—, —C(R3)₂—S—, —R3C=CR3-, —R3C═N—, Si(R3)₂, —Si(R3)₂—Si(R3)₂—, C═O, S═O, SO₂, NR3, PR3 and P(═O)R3;
R1 is any one of hydrogen, deuterium, fluorine, chlorine, bromine, iodine, CN, Si(R6)₃, a straight chain alkyl group, an alkoxyl group, a thioalkyl group with 1-40 carbon atoms, a branched chain with 3-40 carbon atoms, a cyclic alkyl group with 3-40 carbon atoms, an alkoxyl group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, a heteroaryloxy group with 5-60 aromatic rings, an arylalkyl group with 5-60 aromatic rings and a heteroarylalkyl group with 5-60 aromatic rings: R1 may be substituted with one or more R4, R4 is any one of hydrogen, a straight chain alkyl group with 1-22 carbon atoms, an alkoxyl chain with 1-22 carbon atoms, a branched chain with 3-22 carbon atoms, a cyclic alkyl group with 3-22 carbon atoms, an alkoxy chain with 3-22 carbon atoms; one or more non-adjacent carbon atoms in R4 may be substituted with any one of oxygen, sulfur, SO, SO₂, CO, O—CO—O, CO—O, —CH=CH—, —C≡C; one or more hydrogen atoms in R4 may be substituted with any one of fluorine, chlorine, bromine, iodine, CN, an aryl group with 5-40 carbon atoms, a heteroaryl group with 5-40 carbon atoms, an aryloxy group with 5-40 carbon atoms, a heteroaryloxy group with 5-40 carbon atoms and a non-aromatic group; one or more non-adjacent CH₂ in R1 may be substituted with any one of Si(R6)₂, C═NR6, P(═O)(R6), SO, SO₂, NR6, oxygen, sulfur, and CONR6; one or more hydrogen atoms in R1 may be substituted with any of deuterium, fluorine, chlorine, bromine and iodine;
two or more adjacent R1 optionally form any one of a monocyclic aliphatic ring and a polycyclic aliphatic ring, which may be substituted with R4;
R2 is any one of hydrogen, deuterium, fluorine, chlorine, bromine, iodine, CN, Si(R6)₃, a straight chain alkyl group, an alkoxyl group, a thioalkyl group with 1-40 carbon atoms, a branched chain with 3-40 carbon atoms, a cyclic alkyl group with 3-40 carbon atoms, an alkoxyl group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl with 5-60 aromatic rings, a heteroaralkyl with 5-60 aromatic rings, and a benzyl group with 10-30 aromatic rings; R2 may be substituted with one or more R4, R4 is hydrogen, a straight chain alkyl group with 1-22 carbon atoms, an alkoxyl chain with 1-22 carbon atoms, a branched chain with 3-22 carbon atoms, a cyclic alkyl group with 3-22 carbon atoms, an alkoxy chain with 3-22 carbon atoms; one or more non-adjacent carbon atoms in R4 may be substituted with any one of oxygen, sulfur, SO, SO₂, CO, O—CO—O, CO—O, —CH═CH—, —C≡C; one or more hydrogen atoms in R4 may be substituted with any one of fluorine, chlorine, bromine, iodine, CN, an aryl group with 5-40 carbon atoms, a heteroaryl group with 5-40 carbon atoms, an aryloxy group with 5-40 carbon atoms, a heteroaryloxy group with 5-40 carbon atoms, and a non-aromatic group; one or more non-adjacent CH₂ in R1 may be substituted with any of Si(R6)₂, C═NR6, P(═O)(R6), SO, SO₂, NR6, oxygen, sulfur, and CONR6; and one or more hydrogen atoms in R1 may be substituted with any of deuterium, fluorine, chlorine, bromine, and iodine;
one or more non-adjacent CH2 in R2 may be substituted with any one of Si(R6)₂, C═NR6, P(═O)(R6), SO, SO₂, NR6, oxygen, sulfur, CONR6; one or more hydrogen atoms in R2 may be substituted with any one of deuterium, fluorine, chlorine, bromine and iodine;
two or more adjacent R2 form any one of a monocyclic aliphatic ring and a polycyclic aliphatic ring, which may be substituted with R4;
A1, A2. A3 and A4 are each independently any one of an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, and a heteroaralkyl group with 5-60 aromatic rings; and A1 and A2 may each independently substituted with one or more R4;
p, q, t and s are each independently 0 or 1, and p+q>0; and
m and n are each independently any one of 0, 1, 2, 3, and 4.

Optionally, the second compound comprises at least one benzene ring, and a boron atom and/or a nitrogen atom.

Optionally, a chemical structure formula of the second compound comprises any one of:

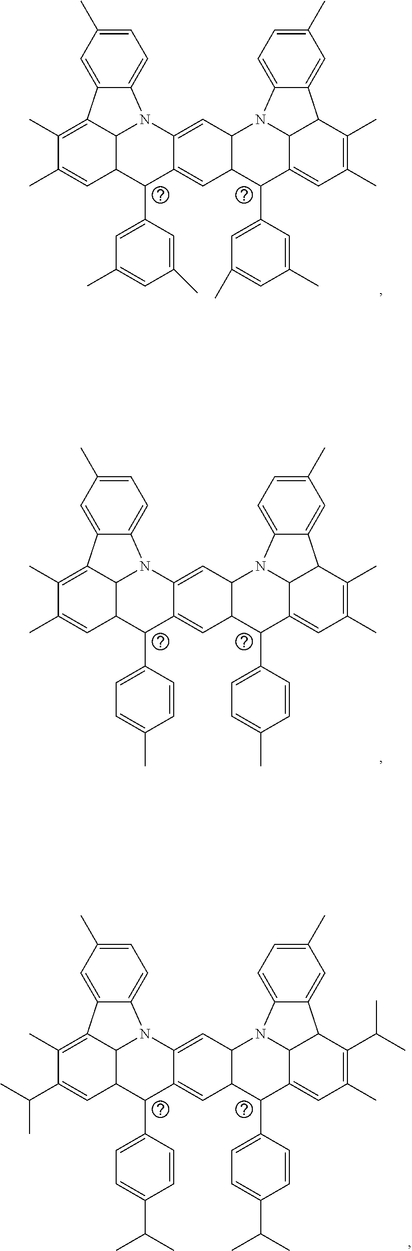

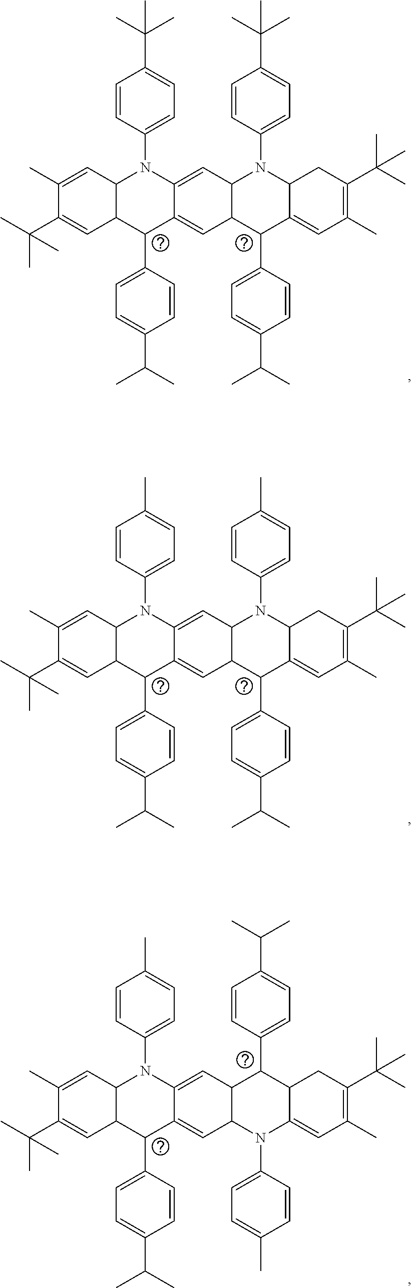

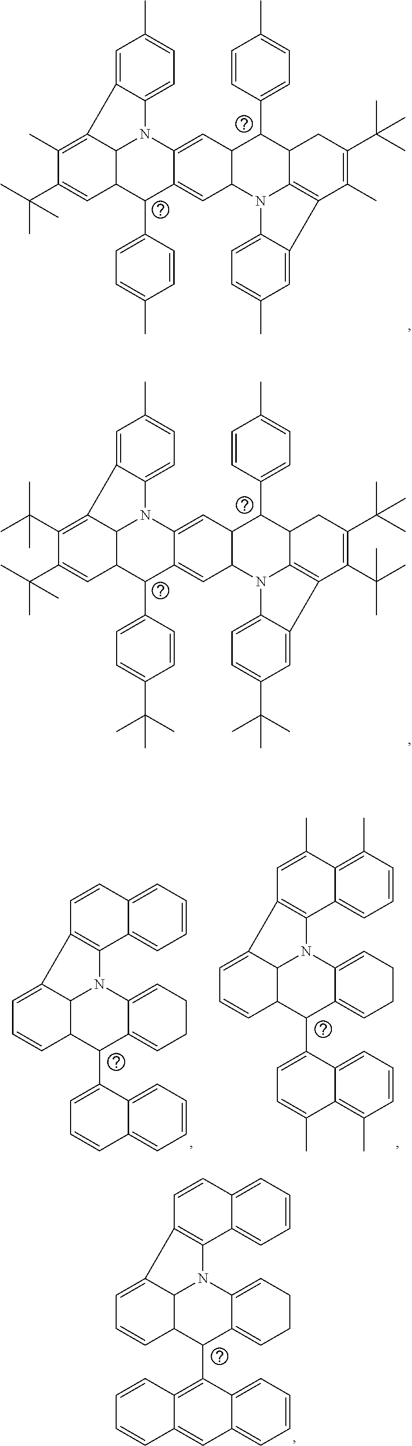

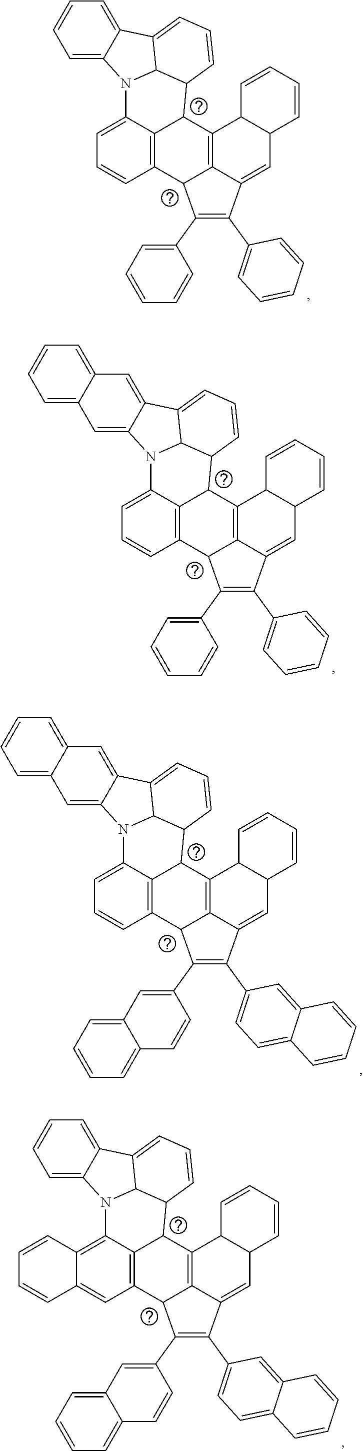

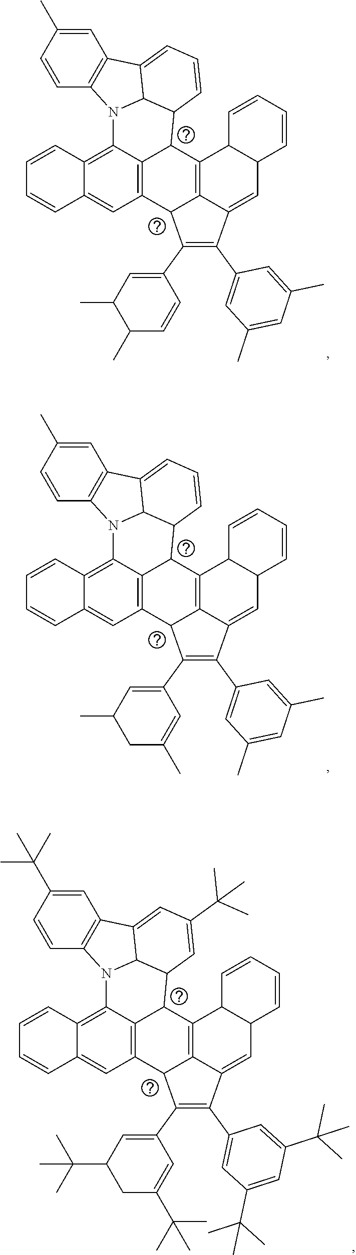

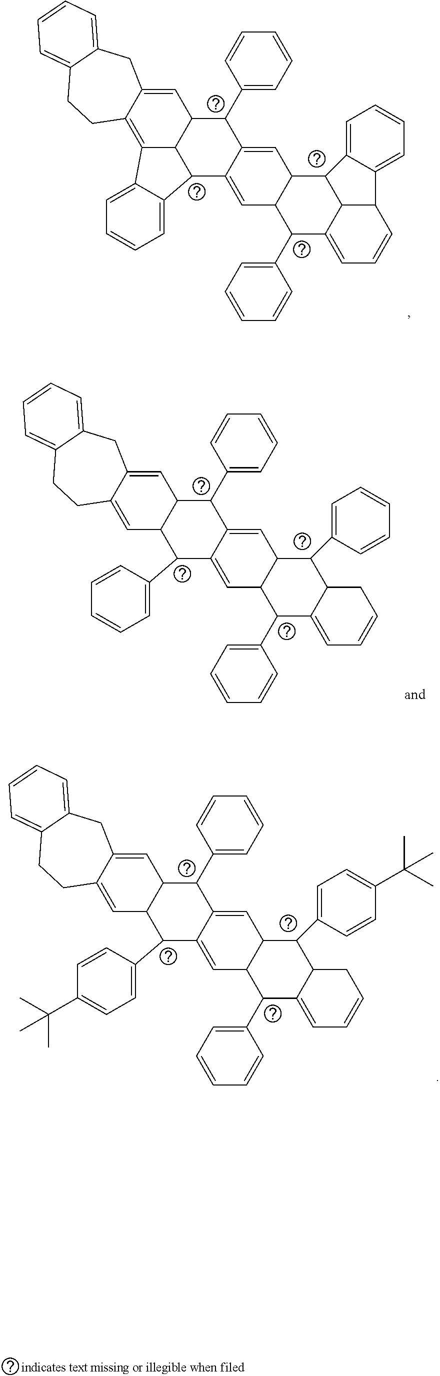

Optionally, the second compound comprises a benzene ring, and a plurality of fourth electron-donating groups and a plurality of third electron-accepting groups bonded to the benzene ring.

Optionally, a chemical structure formula of the second compound comprises any one of:

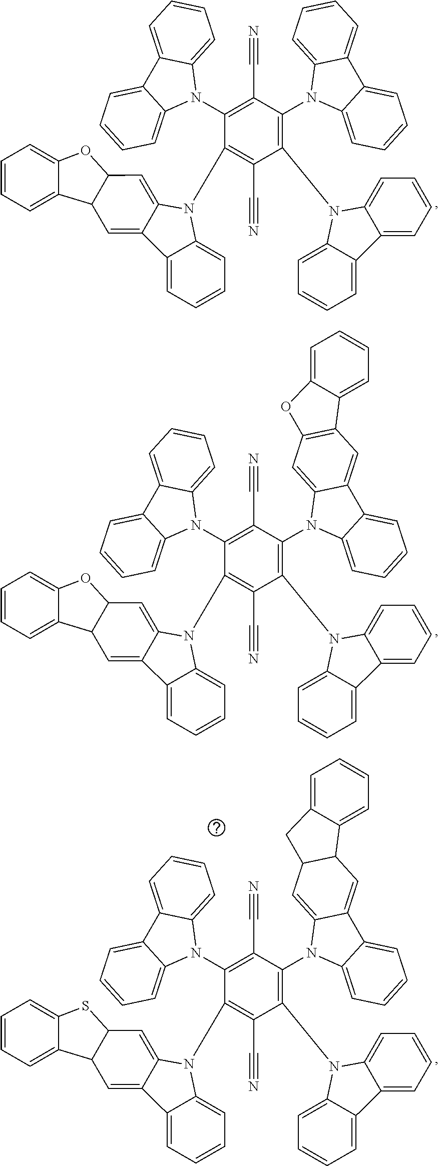

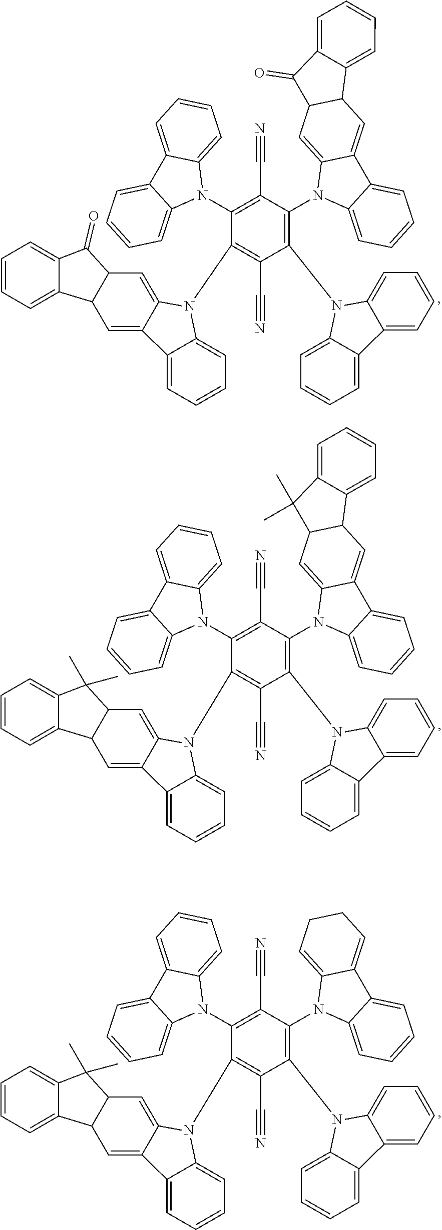

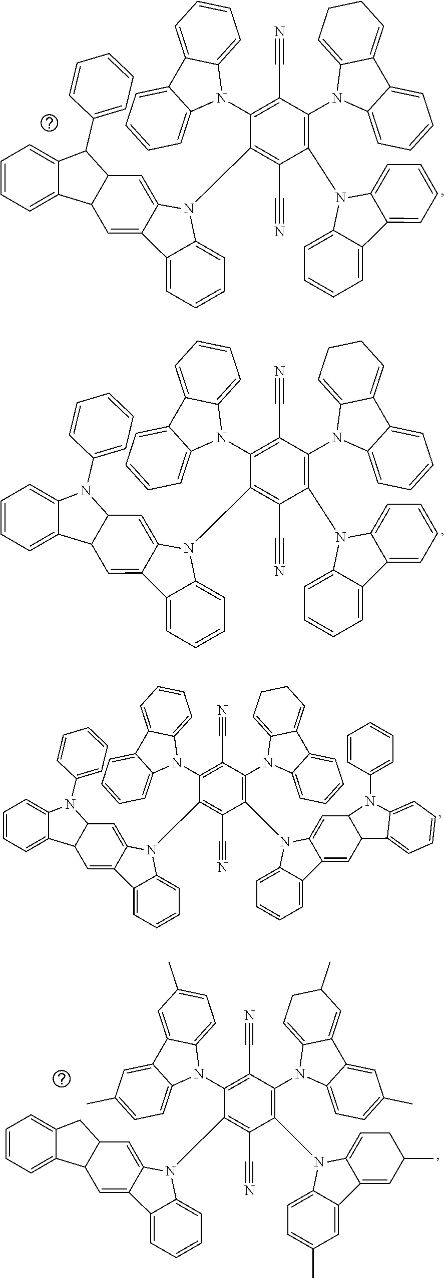

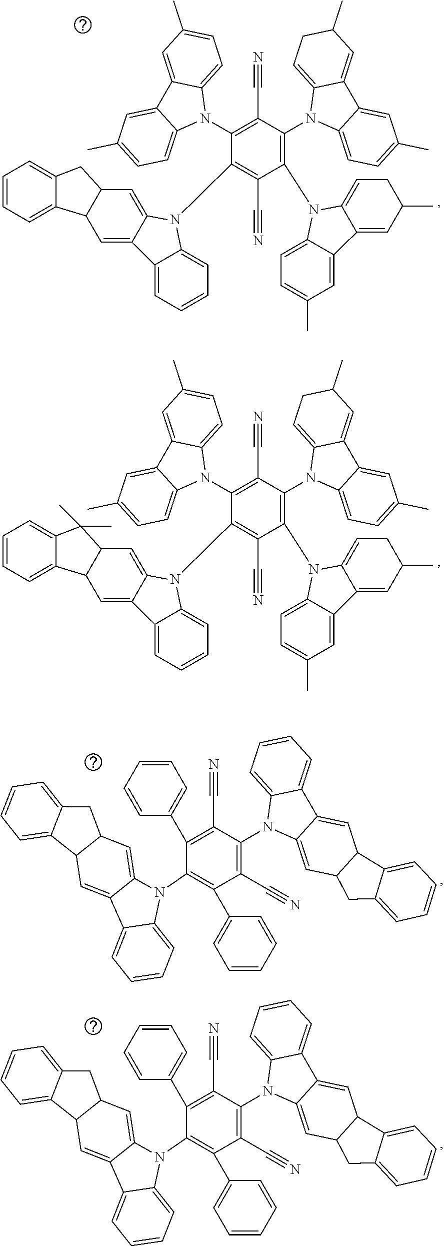

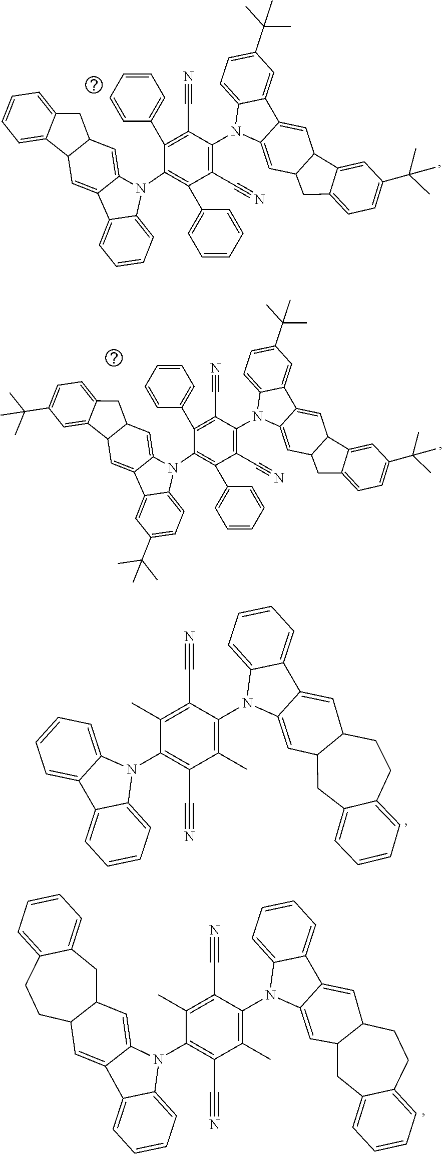

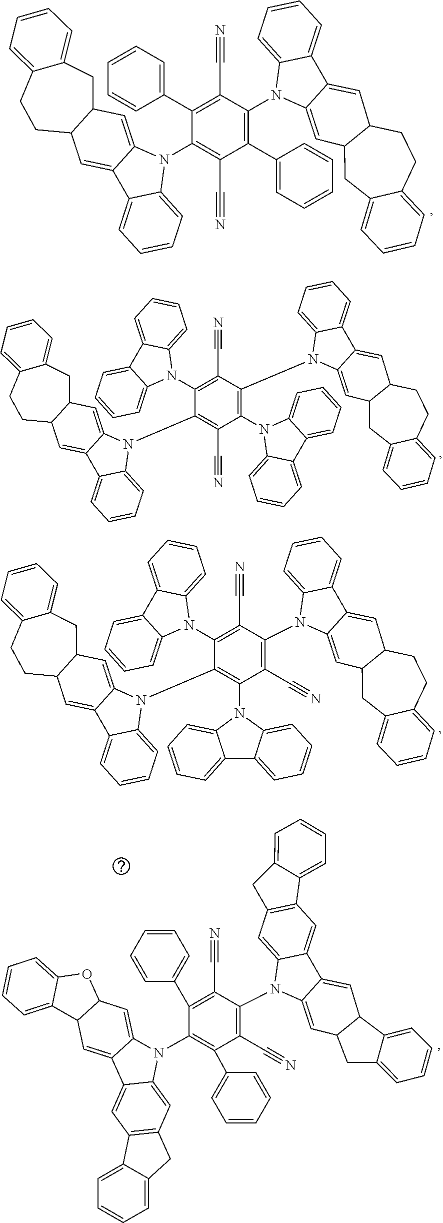

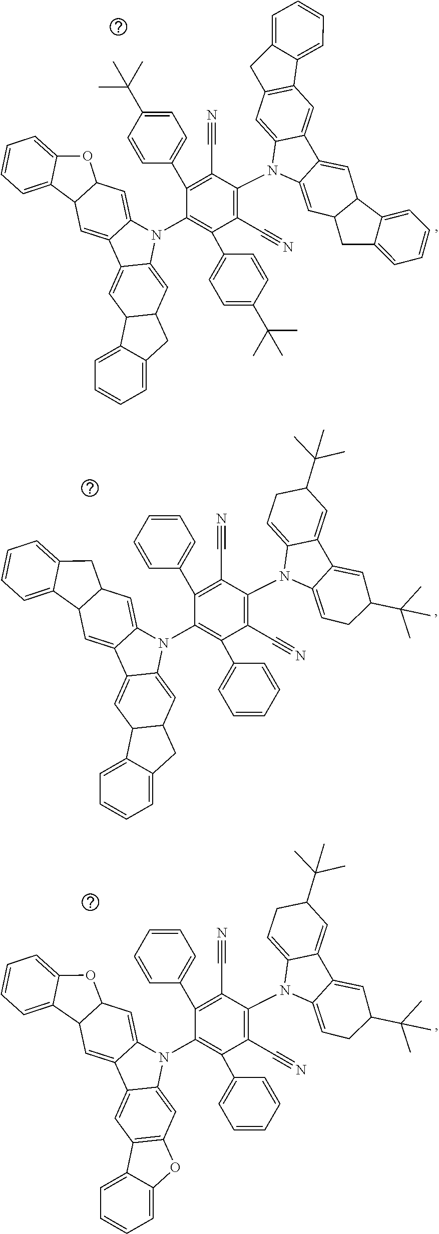

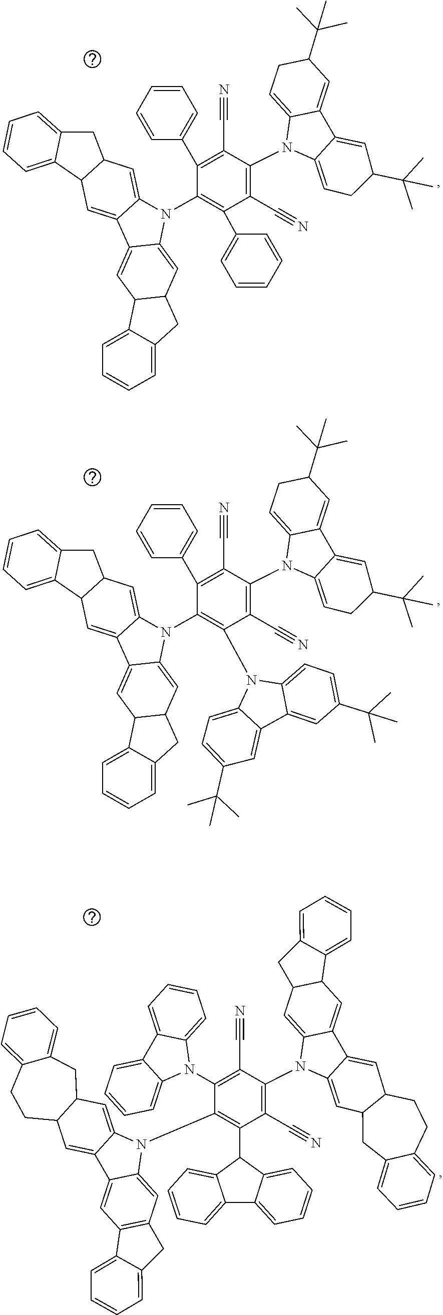

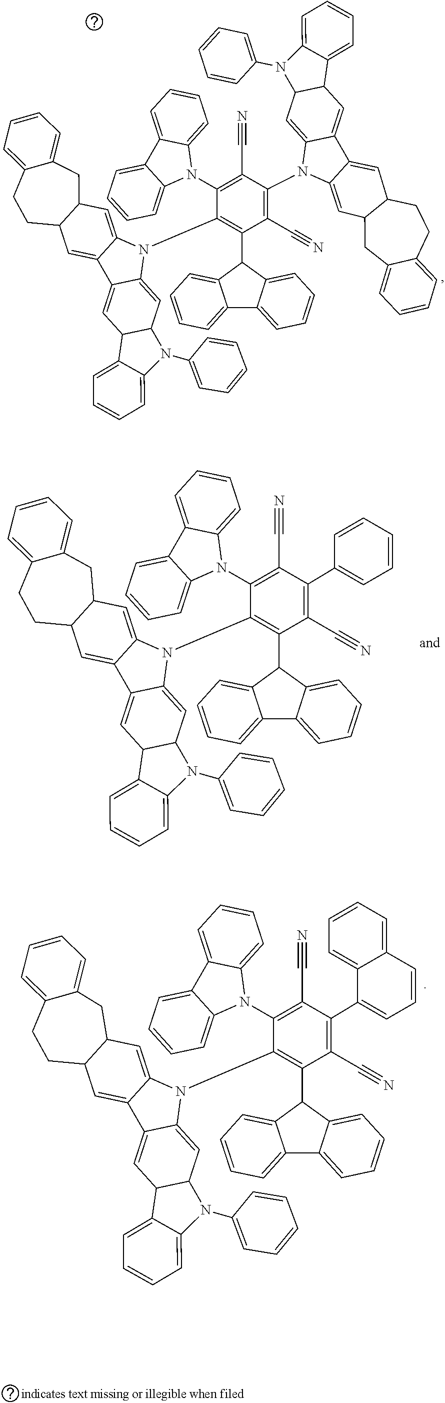 [SMILES: N#Cc1c(C2c3ccccc3-c3ccccc32)c(-n2c3c(c4c2=CC2C(C=4)c4ccccc4N2c2ccccc2)=CC2CCc4ccccc4CC2C=3)c(-n2c3ccccc3c3ccccc32)c(C#N)c1-n1c2c(c3c1=CC1C(C=3)c3ccccc3N1c1ccccc1)=CC1CCc3ccccc3CC1C=2 ; N#Cc1c(-c2ccccc2)c(C#N)c(-n2c3ccccc3c3ccccc32)c(-n2c3c(c4c2=CC2C(C=4)c4ccccc4N2c2ccccc2)=CC2CCc4ccccc4CC2C=3)c1C1c2ccccc2-c2ccccc21 ; N#Cc1c(-c2cccc3ccccc23)c(C#N)c(-n2c3ccccc3c3ccccc32)c(-n2c3c(c4c2=CC2C(C=4)c4ccccc4N2c2ccccc2)=CC2CCc4ccccc4CC2C=3)c1C1c2ccccc2-c2ccccc21]

On the other hand, an embodiment of the present application provides a light-emitting device comprising the above light-emitting layer.

On the other hand, an embodiment of the present application provides a display apparatus comprising the above light-emitting device.

The above description is only a summary of technical schemes of the present disclosure, which can be implemented according to contents of the specification in order to better understand technical solution of the present disclosure; and in order to make above and other objects, features and advantages of the present disclosure more obvious and understandable, detailed description of the present disclosure is particularly provided in the following.

### BRIEF DESCRIPTION OF THE DRAWINGS

In order to more clearly illustrate technical solutions in the embodiments of the present application or in the conventional technology, the figures that are required to describe the embodiments or the conventional technology are briefly introduced below. Apparently, the figures described below are embodiments of the present application, and a person skilled in the art may obtain other figures according to these figures without paying creative efforts.

FIG. 1 is a schematic structure diagram of a light emitting device provided in an embodiment of the present application:

FIG. 2 is a schematic structure diagram of another light emitting device provided in an embodiment of the present application; and

FIG. 3 is a schematic structure diagram of a display device provided in an embodiment of the present application.

### DEEMPENNAGEED DESCRIPTION OF THE EMBODIMENTS

In order to make the objective, technical solutions and advantages of the embodiments of the present application more clear, the technical solutions in the embodiments of the present application will be clearly and completely described below with reference to the accompanying drawings in the embodiments of the present application. Apparently, the described embodiments are only some of the embodiments of the present application, rather than all of the embodiments. Based on the embodiments in the present application, all other embodiments obtained by those of ordinary skill in the art without creative efforts fall within the protection scope of the present application.

In the drawings, thicknesses of regions and layers may be exaggerated for clarity. The same reference numerals in the drawings represent the same or similar structures, and thus their detailed description will be omitted In addition, the drawings are only schematic illustrations of the present application and are not necessarily drawn to scale.

In the embodiments of the present application, unless otherwise indicated, “plurality” means two or more; orientations or positional relationships indicated by the term “on” and the like are based on the orientations or positional relationships shown in the drawings. They and are only intended to facilitate and simplify the description of the present application, and are not intended to indicate or imply that the structure or element referred to must have a specific orientation, be constructed and operated in a specific orientation, and therefore are not be construed as limitations of the present application.

Unless stated otherwise in the context, throughout the description and the claims, the term “comprise” is interpreted as the meaning of opened containing, i.e., “including but not limited to”. In the description of the present disclosure, the terms “one embodiment”, “some embodiments”, “exemplary embodiments”. “example”, “specific example” or “some examples” are intended to indicate that specific features, structures, materials or characteristics related to the embodiment or example are comprised in at least one embodiment or example of the present application. The illustrative indication of the above terms does not necessarily refer to the same one embodiment or example. Moreover, the specific features, structures, materials or characteristics may be comprised in any one or more embodiments or examples in any suitable manner.

In the embodiments of the present application, terms such as “first” and “second” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

With the development of science and technology, OLED light-emitting devices have been widely used due to their excellent performance. The light-emitting modes of OLED light-emitting devices are divided into phosphorescence and fluorescence.

Phosphorescent materials have a strong spin-orbit coupling effect from the center of the heavy atoms, which enhances the intersystem crossing of luminescent molecules and may effectively utilize electrical excitation, so that the singlet excitons generated after excitation may be converted into triplet excitons and may emit light when transitioning to the ground state, and the IQE of phosphorescent OLED light-emitting devices may reach 100%. However, since phosphorescent materials usually use heavy metals as the center of heavy atoms, phosphorescent OLED light-emitting devices have problems such as high price, serious roll-off of device efficiency, and severe pollution.

Therefore, fluorescent OLED light-emitting devices came into being to avoid the use of heavy metal elements. However, traditional organic fluorescent materials produce singlet excitons and triplet excitons in a ratio of 25:75 when excited. 25% of the singlet excitons emit fluorescence when transitioning to the ground state, and 75% of the triplet excitons do not emit light when transitioning to the ground state. Since the high proportion of triplet excitons cannot be used for luminescence, the luminous efficiency of traditional fluorescent light-emitting materials will inevitably low, so that the IQE of OLED light-emitting devices based on fluorescence may only reach its theoretical limit value (generally only up to 25%), resulting in low luminous efficiency and poor luminous performance of OLED light-emitting devices based on traditional fluorescence.

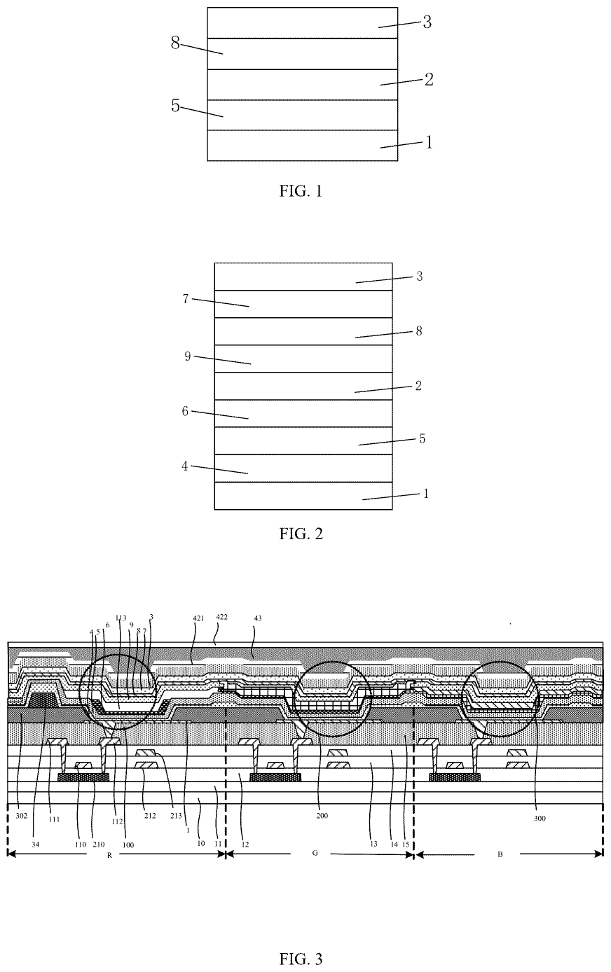

Based on the above, an embodiment of the present application provides a light-emitting layer. As shown in FIG. 1, the light-emitting layer 2 at least includes a first thermally activated delayed fluorescent material, a reverse intersystem crossing rate kRISC of the first thermally activated delayed fluorescent material satisfies: kRISC>1.0×10⁴ s⁻¹; a photoluminescence quantum yield PLQY of the first thermally activated delayed fluorescent material in a pure film state satisfies: PLQY≥50% a horizontal dipole ratio θ// of the first thermally activated delayed fluorescent material satisfies: θ//>67%.

The light-emitting layer at least including the first thermally activated delayed fluorescent material means that: the light-emitting layer only includes the first thermally activated delayed fluorescent material, in which case the light-emitting layer is a film layer composed of a single material, and the manufacturing process is relatively simple; or, in addition to the first thermally activated delayed fluorescent material, the light-emitting layer further includes other materials. In the case where the light-emitting layer includes the first thermally activated delayed fluorescent material and other materials, the first thermally activated delayed fluorescent material may be used as a host material, and the other materials may be doped into the first thermally activated delayed fluorescent material as guest materials.

The above light-emitting layer may be any one of a red light-emitting layer, a green light-emitting layer or a blue light-emitting layer. In this case, the light-emitting layer may be used for emitting light of a single color. The light-emitting device may include three light-emitting layers, namely, a red light-emitting layer, a green light-emitting layer or a blue light-emitting layer; of course, it may also include only one light-emitting layer, for example, only multiple red light-emitting layers, or only multiple green light-emitting layers, or only multiple blue light-emitting layers. The details may be determined according to actual requirements.

The reverse intersystem crossing rate kRISC of the above first thermally activated delayed fluorescent material is not specifically limited here. For example, the reverse intersystem crossing rate kRISC of the above first thermally activated delayed fluorescent material may be 1.0×10⁵ s₋₁, 1.0×10⁶ s₋₁, 1.0×10⁷ s⁻¹ or 1.0×10⁸ s₋₁, etc.

The photoluminescence quantum yield PLQY of the first thermally activated delayed fluorescent material in a pure film state is not specifically limited here. For example, the photoluminescence quantum yield PLQY of the first thermally activated delayed fluorescent material in a pure film state may be 50%, 70%, 80% or 90%, etc. Further, optionally, the photoluminescence quantum yield PLQY of the first thermally activated delayed fluorescent material in a pure film state satisfies: PLQY≥90%. Specifically, the photoluminescence quantum yield PLQY of the first thermally activated delayed fluorescent material in a pure film state may be 91%, 93%, 95% or 97%, etc.

The horizontal dipole ratio θ// of the first thermally activated delayed fluorescent material is not specifically limited. For example, the horizontal dipole ratio θ// of the first thermally activated delayed fluorescent material may be 68%, 70%, 80% or 90%, etc.

An embodiment of the present application provides a light-emitting layer, which at least includes: a first thermally activated delayed fluorescent material, wherein the reverse intersystem crossing rate kRISC of the first thermally activated delayed fluorescent material satisfies: kRISC>1.0×10⁴ s₋₁; the photoluminescence quantum yield PLQY of the first thermally activated delayed fluorescent material in a pure film state satisfies: PLQY≥500%; the horizontal dipole ratio θ// of the first thermally activated delayed fluorescent material satisfies: θ//>67%. The first thermally activated delayed fluorescent material (TADF) produce 25% singlet excitons and 75% triplet excitons when excited, and only 25% of the singlet excitons emit fluorescence when transitioning to the ground state. Since the reverse intersystem crossing rate kRISC of the first thermally activated delayed fluorescent material provided in the embodiment of the present application is relatively large, a energy level difference between a singlet state energy level of the first thermally activated delayed fluorescent material and a triplet state energy level of the first thermally activated delayed fluorescent material is relatively small, and the smaller the energy level difference between the singlet state and the triplet state, the more conducive to reverse intersystem crossing. Therefore, 75% of the triplet excitons in the first thermally activated delayed fluorescent material may more easily reverse intersystem cross to the singlet state to form singlet excitons, and the produced singlet excitons emit fluorescence when excited. That is, a high proportion of triplet excitons that originally could not participate in luminescence are convened into singlet excitons that may participate in luminescence, so that the utilization rate of triplet excitons is greatly improved, the luminescence efficiency of the the luminescent layer is effectively improved, and the luminescence efficiency and luminescence performance of the luminescent device using the above light-emitting layer is improved, and the user experience is good.

In addition, since the first thermally activated delayed fluorescent material has a rigid molecular framework with multiple intermolecular interactions and the molecular structure may be twisted, it may effectively reduce or even suppress molecular motion and geometric vibration, so that non-radiative attenuation caused by concentration quenching may be greatly reduced, and the luminous efficiency and luminous performance of the light-emitting device using the above light-emitting layer may be improved.

Optionally, the energy level difference ΔEST1 between the singlet state energy level and the triplet state energy level of the first thermally activated delayed fluorescent material satisfies: ΔEST1≤0.15 eV.

Here, the energy level difference ΔEST1 between the singlet state energy level and the triplet state energy level of the first thermally activated delayed fluorescent material is not specifically limited. For example, the energy level difference ΔEST1 between the singlet state energy level and the triplet state energy level of the first thermally activated delayed fluorescent material may be 0.05 eV, 0.1 eV, 0.13 eV or 0.15 eV, etc.

An embodiment of the present application provides a light-emitting layer, in light-emitting layer, the energy level difference ΔEST1 between the singlet state energy level 1 and the triplet state energy level of the first thermally activated delayed fluorescent material is very small, which is conducive to confining excitons in the first thermally activated delayed fluorescent material emitter, and the smaller the energy level difference between the singlet state and the triplet state, the more conducive to reverse intersystem crossing, so that 75% of the triplet excitons in the first thermally activated delayed fluorescent material may more easily reverse intersystem cross to the singlet state to produce singlet excitons, and the produced singlet excitons emit fluorescence when excited. That is, a high proportion of triplet excitons that originally could not participate in luminescence are convened into singlet excitons that may participate in luminescence, so that the utilization rate of triplet excitons is greatly improved, the luminescence efficiency of the light-emitting layer is effectively improved, and the luminescence efficiency and luminescence performance of the light-emitting device using the above light-emitting layer is improved.

Optionally, a general structure formula of the first thermally activated delayed fluorescent material is:

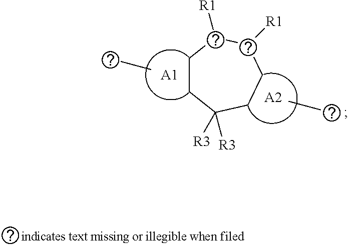

wherein R1-R3 are each independently any one of hydrogen, deuterium, fluorine, chlorine, bromine, iodine, CN, Si(R6)₃, a straight chain alkyl group, an alkoxyl group, a thioalkyl group with 1-40 carbon atoms, a branched chain with 3-40 carbon atoms, a cyclic alkyl group with 3-40 carbon atoms, an alkoxyl group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, and a heteroaralkyl group with 5-60 aromatic rings; R1-R3 may each independently be substituted with one or more R4 s, R4 is any one of hydrogen, a straight chain alkyl group with 1-22 carbon atoms, an alkoxyl group with 1-22 carbon atoms, a branched chain with 3-22 carbon atoms, a cyclic alkyl group with 3-22 carbon atoms and an alkoxyl group with 3-22 carbon atoms; one or more non-adjacent carbon atoms in R4 may be substituted with any one of oxygen, sulfur, SO, SO₂, CO, O—CO—O, CO—O, —CH═CH—, —C≡C; one or more hydrogen in R4 may be substituted with any one of fluorine, chlorine, bromine, iodine, CN, an aryl group with 5-40 carbon atoms, a heteroaryl group with 5-40 carbon atoms, an aryloxy group with 5-40 carbon atoms, a heteroaryloxy group with 5-40 carbon atoms, and a non-aromatic group; one or more non-adjacent CH₂ in R1-R3 may be substituted with any one of Si(R6)₂, C═NR6, P(═O)(R6), SO, SO₂, NR6, oxygen, sulfur, and CONR6; and one or more hydrogen in R1-R3 may be substituted with any one of deuterium, fluorine, chlorine, bromine, and iodine; two or more adjacent R1-R3 form any one of monocyclic and polycyclic aliphatic rings, which may be substituted with R4; at least one of R2 and R3 is not hydrogen; R1 is substituted with at least one cyano group, R1 contains t nitrogen atoms, and t is any one of 1, 2 and 3; A1 and A2 are each independently any one of an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, and a heteroaralkyl group with 5-60 aromatic rings, and A1 and A2 may each independently be substituted with one or more R4; m and n are each independently any one of 0, 1, 2, 3 and 4; and p and q are each independently 0 or 1, and p+q≠0.

Optionally, the first thermally activated delayed fluorescent material includes diphenylpyridine or nitrogen-containing diphenylpyridine. Thus, the first thermally activated delayed fluorescent material has a large steric hindrance, and the diphenylpyridine structure has a large twist angle, so that the concentration quenching may be effectively suppressed, and the photoluminescence quantum yield PLQY of the first thermally activated delayed fluorescent material in a pure film state is large, and the luminous efficiency and luminous performance of the light-emitting device using the above light-emitting layer may be effectively improved.

Optionally, when the first thermally activated delayed fluorescent material includes the nitrogen-containing diphenylpyridine, a general structure formula of the first thermally activated delayed fluorescent material is:

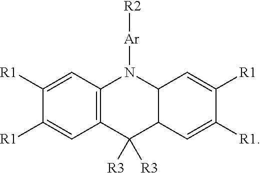

Optionally, R3 is selected from any one of:

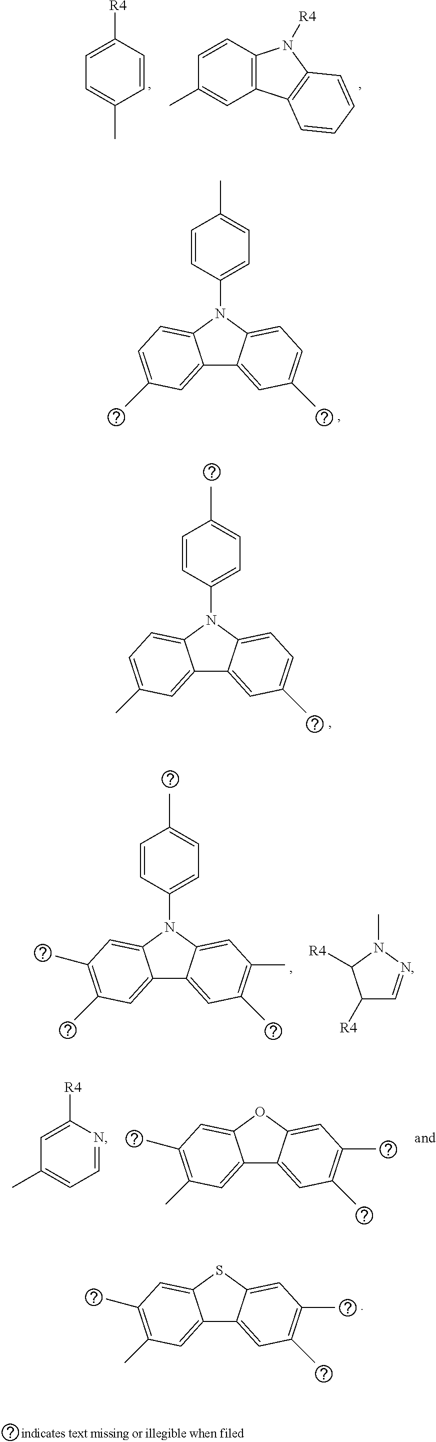

Optionally, a chemical structure formula of the first thermally activated delayed fluorescent material includes any one of:

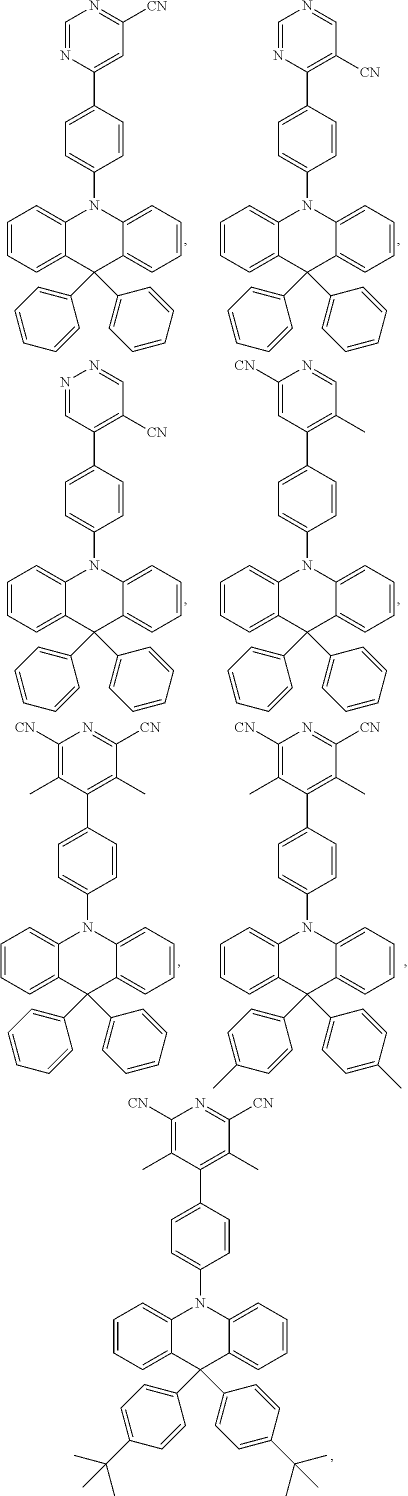

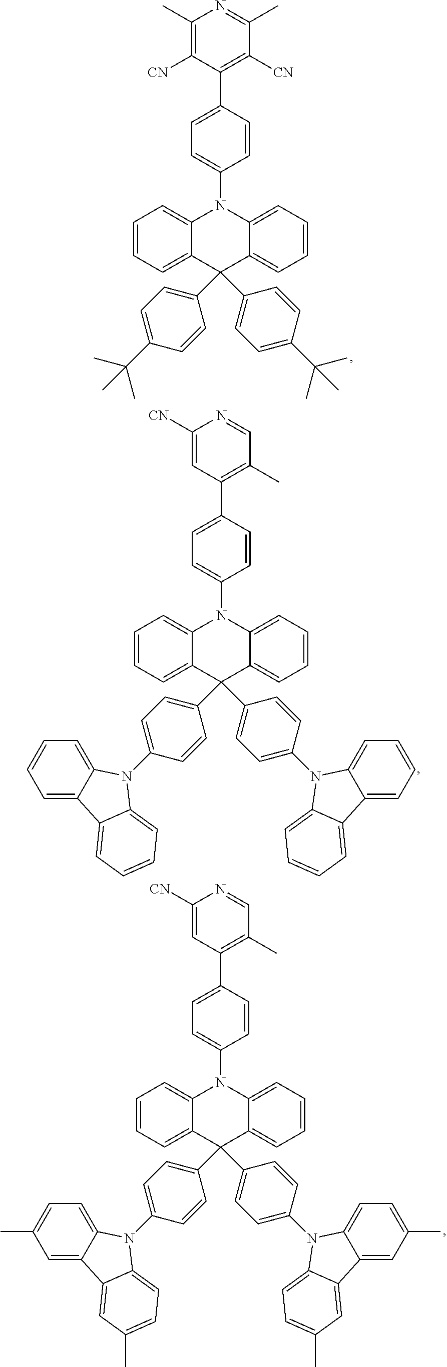

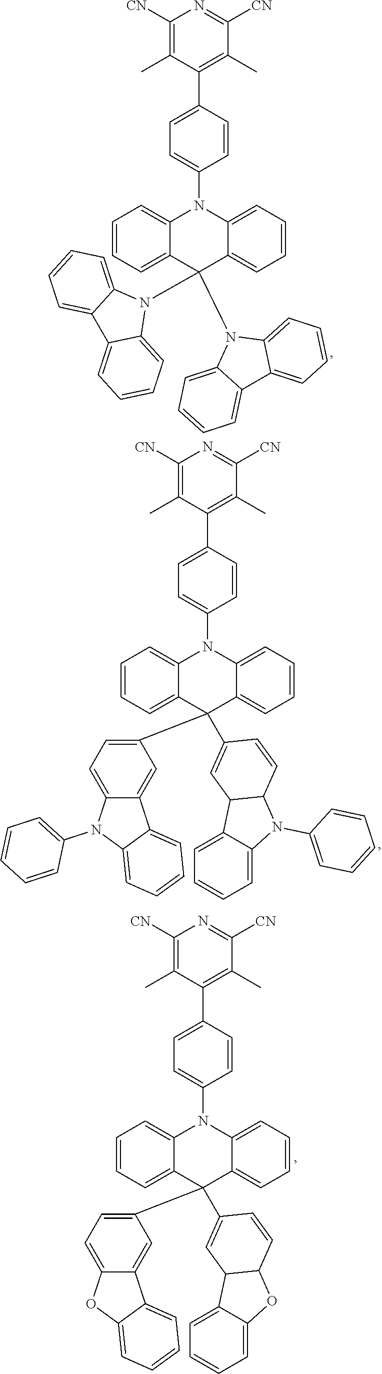

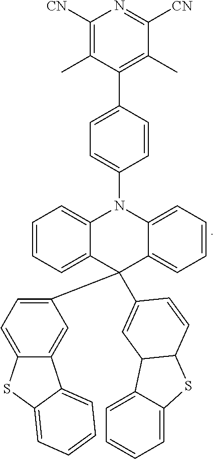

Optionally, the light-emitting layer further includes a first compound doped in the first thermally activated delayed fluorescent material; an absolute value of the difference between reorganization energy λRISC of the first compound and the energy level difference ΔEST2 between the singlet state energy level and the triplet state energy level of the first compound satisfies: |λRISC-ΔEST2|≤0.1 eV.

The doping concentration of the first compound is not specifically limited here. For example, the doping concentration range of the first compound may include less than or equal to 50%. Specifically, the doping concentration of the first compound may be 10%, 20%, 30%, 40% or 50%, etc. Further optionally, the doping concentration range of the first compound may include less than or equal to 30%. Specifically, the doping concentration of the first compound may be 10%, 20% or 30%, etc.

The absolute value of the difference between the reorganization energy λRISC of the above first compound and the energy level difference ΔEST2 between the singlet state energy level and the triplet state energy level of the first compound |λRISC-ΔEST2| is not specifically limited. For example, the absolute value of the difference between the reorganization energy λRISC of the above first compound and the energy level difference ΔEST2 between the singlet state energy level and the triplet state energy level of the first compound |λRISC-ΔEST2| may be 0.01 eV, 0.03 eV, 0.08 eV or 0.1 eV, etc.

An embodiment of the present application provides a light-emitting layer including a first thermally activated delayed fluorescent material and a first compound. On the one hand, the first thermally activated delayed fluorescent material may perform effective energy transfer while acting as a host material, thereby effectively improving the luminous efficiency and luminous performance of the light-emitting device using the above light-emitting layer; on the other hand, since the absolute value of the difference between the reorganization energy λRISC of the first compound and the energy level difference ΔEST2 between the singlet state energy level and the triplet state energy level of the first compound is small, the up-conversion ability (i.e., the ability of the triplet exciton in the first compound to reverse intersystem cross to the singlet state to form a singlet exciton) may be improved, thereby effectively improving the luminous efficiency and luminous performance of the light-emitting device using the above light-emitting layer.

Optionally, the first compound is a second thermally activated delayed fluorescent material; and the reverse intersystem crossing rate kRISC2 of the first compound satisfies: kRISC2>1.0×10⁴ s⁻¹.

The reverse intersystem crossing rate kRISC of the above first compound is not specifically limited. For example, the reverse intersystem crossing rate kRISC of the above first compound may be 1.0×10⁵ s₋₁, 1.0×10⁶ s₋₁, 1.0×10⁷ s₋₁ or 1.0×10⁸ s₋₁, etc.

An embodiment of the present application provides a light-emitting layer including a first compound. Since the first compound is a second thermally activated delayed fluorescent material and the reverse intersystem crossing rate kRISC is large, the energy level difference between the singlet state energy level and the triplet state energy level of the first compound is small, and the smaller the energy level difference between the singlet state and the triplet state, the more conducive it is to reverse intersystem crossing. Then, 75% of the triplet excitons in the first compound can more easily reverse intersystem cross to the singlet state to form singlet excitons, and the formed singlet excitons emit fluorescence when excited. That is, a high proportion of triplet excitons that originally cannot participate in luminescence are converted into singlet excitons that may participate in luminescence, thereby greatly improving the utilization rate of triplet excitons, and then effectively improving the luminescence efficiency and luminescence performance of the light-emitting device using the above light-emitting layer.

Optionally, a general structure formula of the first compound is:

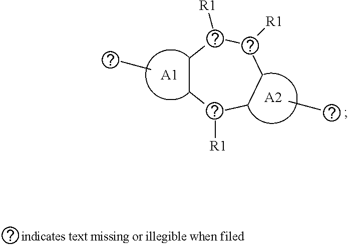

wherein X, Y and Z are each independently any one of carbon, nitrogen, BR3, C(R3)₂, —C(R3)₂—C(R3)₂—, —C(R3)₂—O—, —C(R3)₂—S—, —R3C═CR3-. —R3C═N—, Si(R3)₂, —Si(R-3)₂, —Si(R3)₂—, C═O, oxygen, sulfur, S═O, SO₂, NR3, PR3, and P(═O)R3; R1 is any one of hydrogen, deuterium, fluorine, chlorine, bromine, iodine, CN, Si(R6)₃, a straight chain alkyl group, an alkoxy group, a thioalkyl group with 1-40 carbon atoms, a branched chain alkyl group with 3-40 carbon atoms, a cyclic alkyl group with 3-40 carbon atoms, an alkoxy group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, and a heteroaryloxy group with 5-60 aromatic rings, an aralkyl group with 5-60 aromatic rings, and a heteroaralkyl group with 5-60 aromatic rings; R1 may be substituted with one or more R4, R4 is any one of hydrogen, a straight chain alkyl group with 1-22 carbon atoms, an alkoxy chain with 1-22 carbon atoms, a branched chain with 3-22 carbon atoms, a cyclic alkyl group with 3-22 carbon atoms, and an alkoxy chain with 3-22 carbon atoms; one or more non-adjacent carbon atoms in R4 may be substituted with any one of oxygen, sulfur, SO, SO₂, CO, O—CO—O, CO—O, —CH═CH—, —C≡C; one or more hydrogen atoms in R4 may be substituted with any one of fluorine, chlorine, bromine, iodine, CN, an aryl group with 5-40 carbon atoms, a heteroaryl group with 5-40 carbon atoms, an aryloxy group with 5-40 carbon atoms, a heteroaryloxy group with 5-40 carbon atoms and a non-aromatic group; one or more non-adjacent CH₂ in R1 may be substituted with any one of Si(R6)₂, C═NR6, P(═O)(R6), SO, SO₂, NR6, oxygen, sulfur and CONR6; and one or more hydrogen atoms in R1 may be substituted with any one of deuterium, fluorine, chlorine, bromine and iodine; two or more adjacent R1 optionally form any one of a monocyclic aliphatic ring and a polycyclic aliphatic ring, which may be substituted with R4; A1 and A2 are each independently any one of an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, and a heteroaralkyl group with 5-60 aromatic rings; and A1 and A2 may each independently be substituted with one or more R4; p, q and t are each independently 0 or 1, and p+q≠0; and m and n are each independently any one of 0, 1, 2, 3 and 4.

Further optionally, m and n are each independently 2.

Optionally, the first compound includes a first electron-donating group, a first electron-accepting group and a first linking group, the first electron-donating group is bonded to the first electron-accepting group through the first linking group, and the first linking group includes a benzene ring or pyridine, so that the first electron-donating group and the first electron-accepting group through a benzene ring or pyridine.

Optionally, a chemical structure formula of the first compound includes any one of:

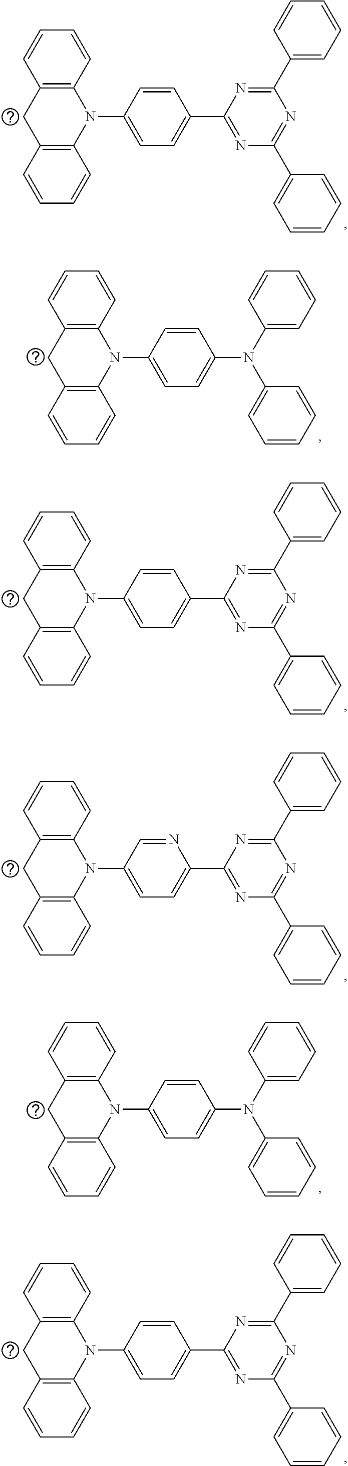

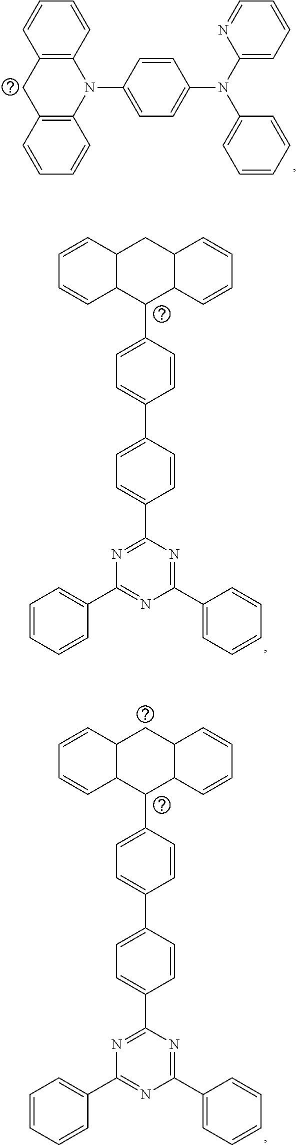 [SMILES: c1ccc(N(c2ccc(N3c4ccccc4Cc4ccccc43)cc2)c2ccccn2)cc1 ; C1=CC2CC3C=CC=CC3C(c3ccc(-c4ccc(-c5nc(-c6ccccc6)nc(-c6ccccc6)n5)cc4)cc3)C2C=C1 ; C1=CC2CC3C=CC=CC3C(c3ccc(-c4ccc(-c5nc(-c6ccccc6)nc(-c6ccccc6)n5)cc4)cc3)C2C=C1]

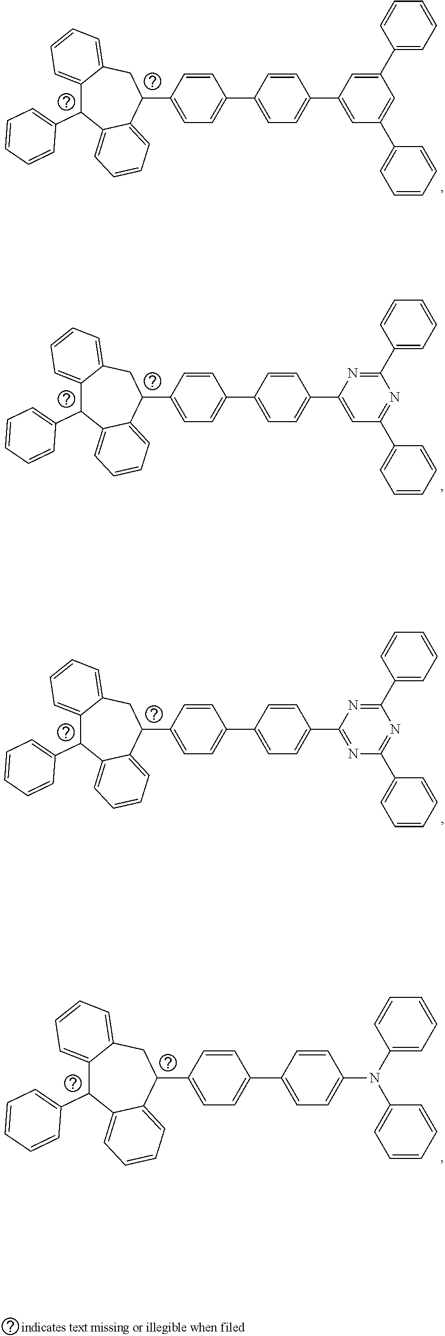

Optionally, the first compound includes a second electron-donating group, a third electron-donating group and a second electron-accepting group, and the second electron-donating group is bonded to the third electron-donating group through the second electron-accepting group, so that the second electron-donating group and the third electron donating-group are bridged through the second electron-accepting group.

Optionally, a chemical structure formula of the first compound includes any one of:

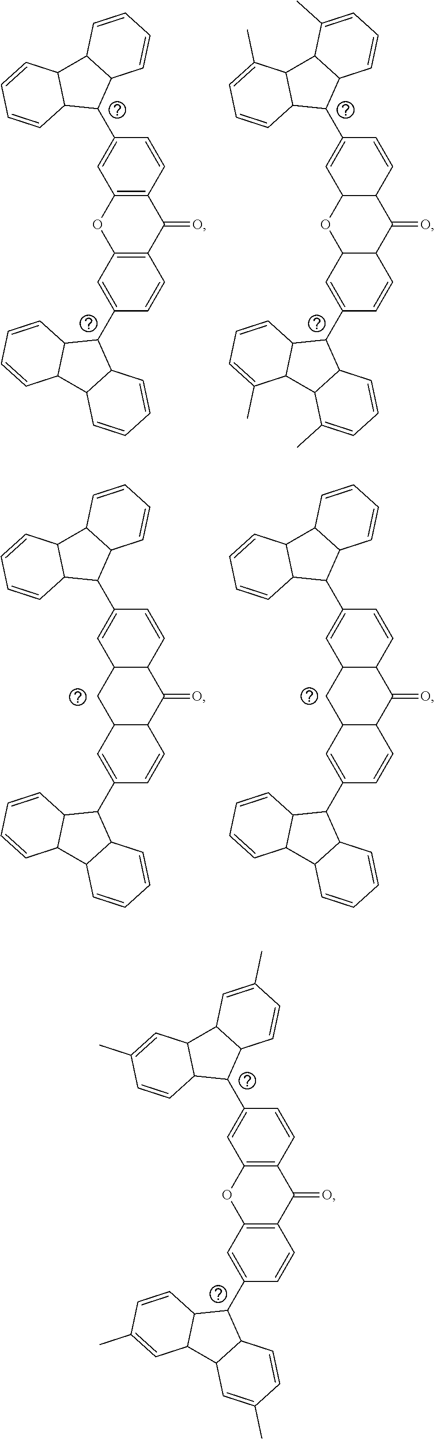 [SMILES: O=c1c2ccc(C3C4C=CC=CC4C4C=CC=CC43)cc2oc2cc(C3C4C=CC=CC4C4C=CC=CC43)ccc12 ; CC1=CC=CC2C(C3=CC4OC5C=C(C6C7C=CC=C(C)C7C7C(C)=CC=CC67)C=CC5C(=O)C4C=C3)C3C=CC=C(C)C3C12 ; O=C1C2C=CC(C3C4C=CC=CC4C4C=CC=CC43)=CC2CC2C=C(C3C4C=CC=CC4C4C=CC=CC43)C=CC12 ; O=C1C2C=CC(C3C4C=CC=CC4C4C=CC=CC43)=CC2CC2C=C(C3C4C=CC=CC4C4C=CC=CC43)C=CC12 ; CC1=CC2C3C=C(C)C=CC3C(c3ccc4c(=O)c5ccc(C6C7C=CC(C)=CC7C7C=C(C)C=CC76)cc5oc4c3)C2C=C1]

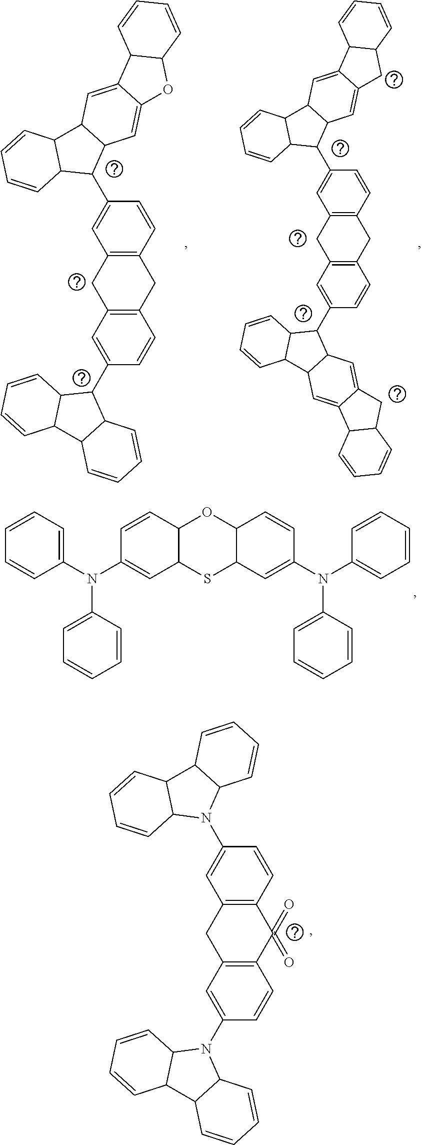

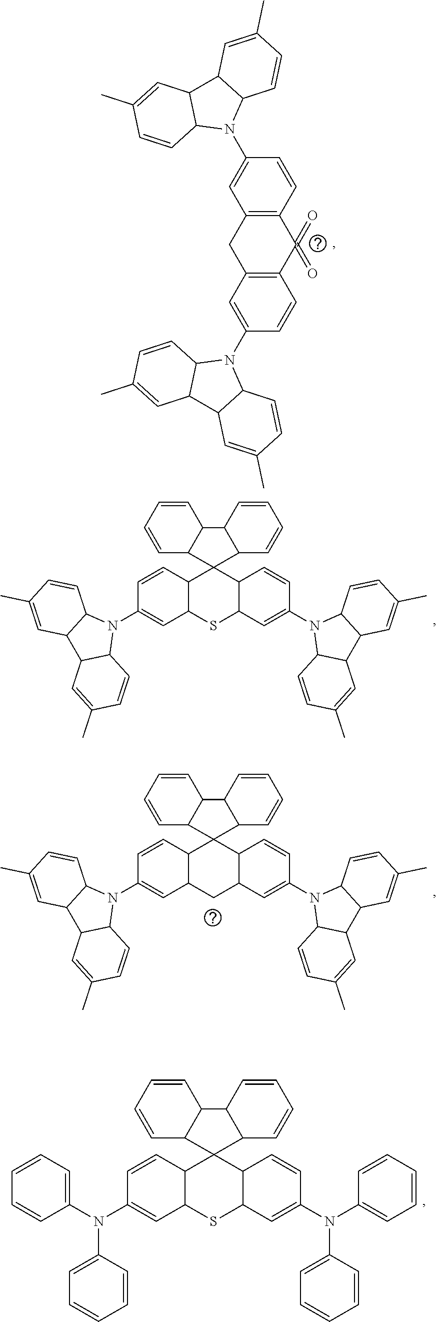

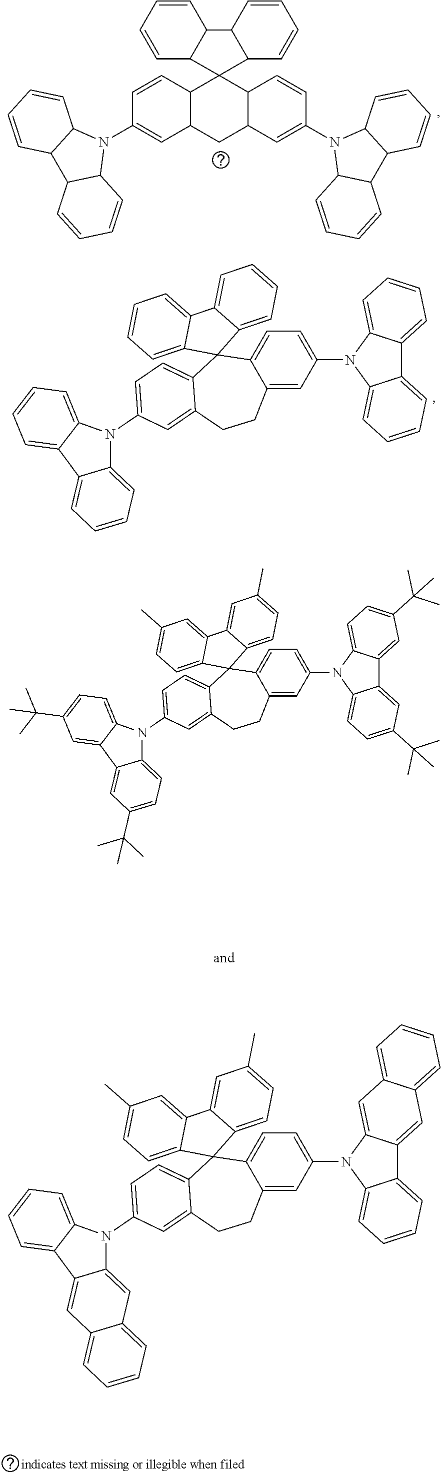

Optionally, the light-emitting layer further includes a second compound doped in the first thermally activated delayed fluorescent material; the triplet state energy level T1 of the first thermally activated delayed fluorescent material satisfies: T₁≥2.7 eV.

The doping concentration of the second compound is not specifically limited here. For example, the doping concentration range of the second compound may include less than or equal to 50%. Specifically, the doping concentration of the second compound may be 10%, 20%, 30%, 40% or 50%, etc. Further optionally, the doping concentration range of the second compound may include less than or equal to 30%, Specifically, the doping concentration of the second compound may be 10%, 20% or 30%, etc.

The triplet state energy level T1 of the first thermally activated delayed fluorescent material is not specifically limited here. For example, the triplet energy level T1 of the first thermally activated delayed fluorescent material may be 2.7 eV, 2.9 eV, 3 eV, 4 eV or 5 eV, etc.

An embodiment of the present application provides a light-emitting layer including a first thermally activated delayed fluorescent material and a second compound. On the one hand, the first thermally activated delayed fluorescent material may perform effective energy transfer while acting as a host material, thereby effectively improving the luminous efficiency and the luminous performance of the light-emitting device using the above light-emitting layer; on the other hand, since the second compound is an emitter of blue light and the triplet state energy level T1 of the first thermally activated delayed fluorescent material is relatively large, so that the luminous efficiency and luminous performance of the light-emitting device using the above light-emitting layer are effectively improved.

Optionally, the second compound is a third thermally activated delayed fluorescent material.

The embodiment of the present application provides a light-emitting layer including a second compound. Since the second compound is a third thermally activated delayed fluorescent material, the energy level difference between the singlet state energy level and the triplet state energy level of the second compound is small, and the smaller the energy level difference between the singlet state and the triplet state, the more conducive to reverse intersystem crossing. Therefore, 75% of the triplet excitons in the second compound may more easily reverse intersystem cross to the singlet state to form singlet excitons, and the formed singlet excitons emit fluorescence when excited. That is, a high proportion of triplet excitons that originally cannot participate in luminescence are converted into singlet excitons that may participate in luminescence, thereby greatly improving the utilization rate of triplet excitons, and then effectively improving the luminescence efficiency and luminescence performance of the light-emitting device using the above light-emitting layer.

Optionally, a general structure formula of the second compound is any one of:

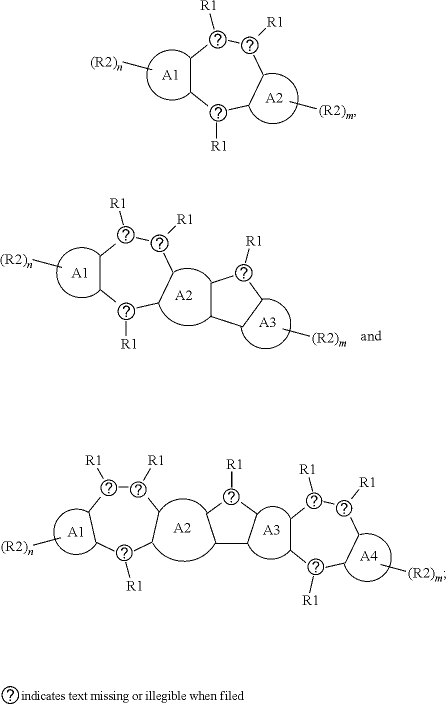

wherein X, Y, Z and W are each independently any one of carbon, nitrogen, boron, oxygen, sulfur, selenium, tellurium, BR3, C(R3)₂, —C(R3)₂—C(R3)₂, —C(R3)₂—O—, —C(R3)₂—S—, —R3C═CR3-, —R3C=N—, Si(R3)₂, —Si(R3)₂—Si(R3)₂—, C═O, S═O, SO₂, NR3, PR3 and P(═O)R3; R1 is any one of hydrogen, deuterium, fluorine, chlorine, bromine, iodine, CN, Si(R6)₃, a straight chain alkyl group, an alkoxyl group, a thioalkyl group with 1-40 carbon atoms, a branched chain with 3-40 carbon atoms, a cyclic alkyl group with 3-40 carbon atoms, an alkoxyl group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, a heteroaryloxy group with 5-60 aromatic rings, an arylalkyl group with 5-60 aromatic rings and a heteroarylalkyl group with 5-60 aromatic rings; R1 may be substituted with one or more R4, R4 is any one of hydrogen, a straight chain alkyl group with 1-22 carbon atoms, an alkoxyl chain with 1-22 carbon atoms, a branched chain with 3-22 carbon atoms, a cyclic alkyl group with 3-22 carbon atoms, and an alkoxy chain with 3-22 carbon atoms; one or more non-adjacent carbon atoms in R4 may be substituted with any one of oxygen, sulfur, SO, SO₂, CO, O—CO—O, CO—O, —CH═CH— and —C≡C; one or more hydrogen atoms in R4 may be substituted with any one of fluorine, chlorine, bromine, iodine, CN, an aryl group with 5-40 carbon atoms, a heteroaryl group with 5-40 carbon atoms, an aryloxy group with 5-40 carbon atoms, a heteroaryloxy group with 5-40 carbon atoms and a non-aromatic group; one or more non-adjacent CH₂ in R1 may be substituted with any one of Si(R6)₂, C═NR6, P(═O)(R6), SO, SO₂, NR6, oxygen, sulfur, and CONR6; one or more hydrogen atoms in R1 may be substituted with any of deuterium, fluorine, chlorine, bromine and iodine; two or more adjacent R1 form any one of a monocyclic aliphatic ring and a polycyclic aliphatic ring, which may be substituted with R4; R2 is any one of hydrogen, deuterium, fluorine, chlorine, bromine, iodine, CN, Si(R6)₃, a straight chain alkyl group, an alkoxyl group, a thioalkyl group with 1-40 carbon atoms, a branched chain with 3-40 carbon atoms, a cyclic alkyl group with 3-40 carbon atoms, an alkoxyl group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, a heteroaralkyl with 5-60 aromatic rings, and a benzyl group with 10-30 aromatic rings; R2 may be substituted with one or more R4, R4 is hydrogen, a straight chain alkyl group with 1-22 carbon atoms, an alkoxyl chain with 1-22 carbon atoms, a branched chain with 3-22 carbon atoms, a cyclic alkyl group with 3-22 carbon atoms, an alkoxy chain with 3-22 carbon atoms; one or more non-adjacent carbon atoms in R4 may be substituted with any one of oxygen, sulfur, SO, SO₂, CO, O—CO—O, CO—O, —CH═CH— and —C≡C, one or more hydrogen atoms in R4 may be substituted with any one of fluorine, chlorine, bromine, iodine, CN, an aryl group with 5-40 carbon atoms, a heteroaryl group with 5-40 carbon atoms, an aryloxy group with 5-40 carbon atoms, a heteroaryloxy group with 5-40 carbon atoms, and a non-aromatic group; one or more non-adjacent CH₂ in R1 may be substituted with any of Si(R6)₂, CλNR6, P(λO)(R6), SO, SO₂, NR6, oxygen, sulfur, and CONR6; one or more hydrogen atoms in R1 may be substituted with any of deuterium, fluorine, chlorine, bromine, and iodine; one or more non-adjacent CH₂ in R2 may be substituted with any one of Si(R6)₂, C═NR6, P(═O)(R6), SO, SO₂, NR6, oxygen, sulfur, CONR6; and one or more hydrogen atoms in R2 may be substituted with any one of deuterium, fluorine, chlorine, bromine and iodine; one or more non-adjacent CH₂ in R2 may be substituted with any one of Si(R6)₂, C═NR6, P(O)(R6), SO, SO₂, NR6, oxygen, sulfur, CONR6; and one or more hydrogen atoms in R2 may be substituted with any one of deuterium, fluorine, chlorine, bromine and iodine; two or more adjacent R2 form any one of a monocyclic aliphatic ring and a polycyclic aliphatic ring, which may be substituted with R4; A1, A2, A3 and A4 are c each independently any one of an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, and a heteroaralkyl group with 5-60 aromatic rings; A1 and A2 may each independently substituted with one or more R4; p, q, t and s are each independently 0 or 1, and p+q>0; and m and n are each independently any one of 0, 1, 2, 3, and 4.

Further optionally, the second compound includes at most three carbazole groups, thereby saving manufacturing process and being simple and easy to implement.

Optionally, the second compound includes at least one benzene ring, and a boron atom and/or a nitrogen atom, so that the second compound has advantages such as strong rigidity, better molecular planarity, and better in-situ vibration, thereby effectively improving the luminous efficiency and luminous performance of the light-emitting device using the above light-emitting layer.

Optionally, a chemical structure formula of the second compound includes any one of:

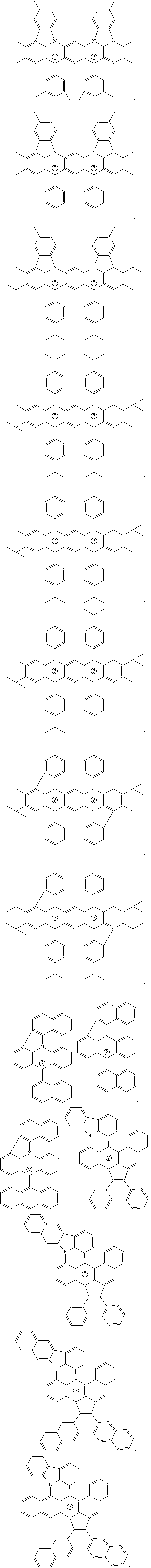

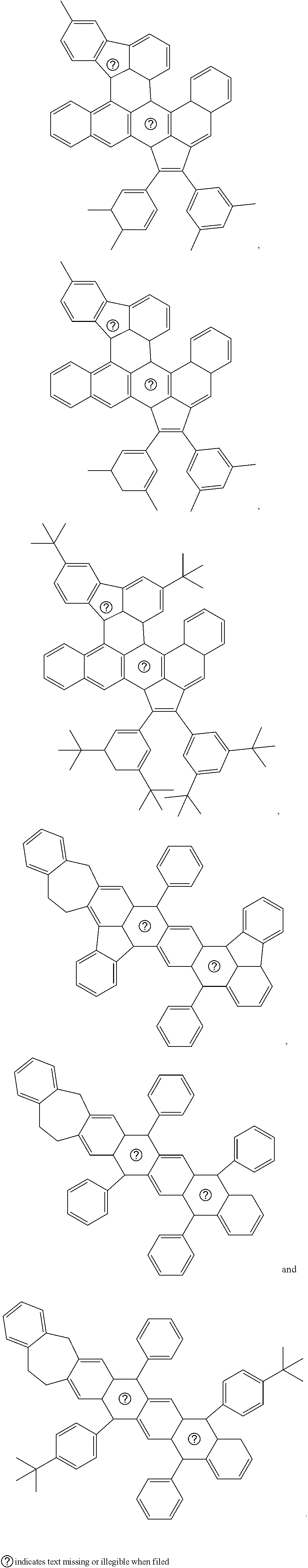

Optionally, the second compound includes a benzene ring, and a plurality of fourth electron-donating groups and a plurality of third electron-accepting groups bonded to the benzene ring. Thus, the emission performance of the second compound may be improved by a plurality of electron-accepting groups with strong electron withdrawing properties and a plurality of electron-donating groups, thereby effectively improving the luminous efficiency and luminous performance of the light-emitting device using the above light-emitting layer.

The type of the fourth electron donating group is not specifically limited here. For example, the fourth electron donating group may include carbazole, thiophene, furan, etc.

The type of the third electron accepting group is not specifically limited here. For example, the third electron accepting group may include a cyano group.

Optionally, a chemical structure formula of the second compound includes any one of:

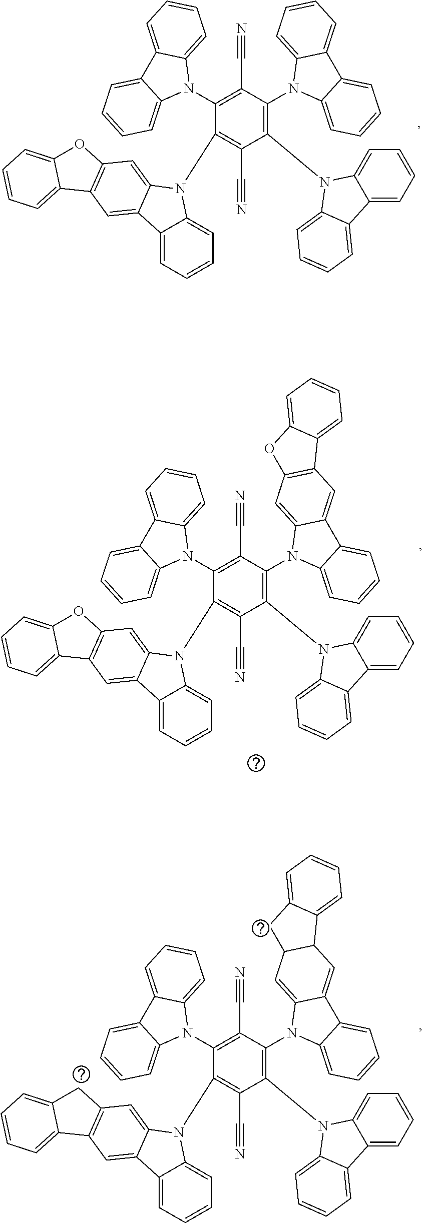 [SMILES: N#Cc1c(-n2c3ccccc3c3ccccc32)c(-n2c3ccccc3c3ccccc32)c(C#N)c(-n2c3ccccc3c3cc4c(cc32)oc2ccccc24)c1-n1c2ccccc2c2ccccc21 ; N#Cc1c(-n2c3ccccc3c3ccccc32)c(-n2c3ccccc3c3cc4c(cc32)oc2ccccc24)c(C#N)c(-n2c3ccccc3c3ccccc32)c1-n1c2ccccc2c2cc3c(cc21)oc1ccccc13 ; N#Cc1c(-n2c3c(c4ccccc42)=CC2c4ccccc4CC2C=3)c(-n2c3ccccc3c3ccccc32)c(C#N)c(-n2c3ccccc3c3cc4c(cc32)Cc2ccccc2-4)c1-n1c2ccccc2c2ccccc21]

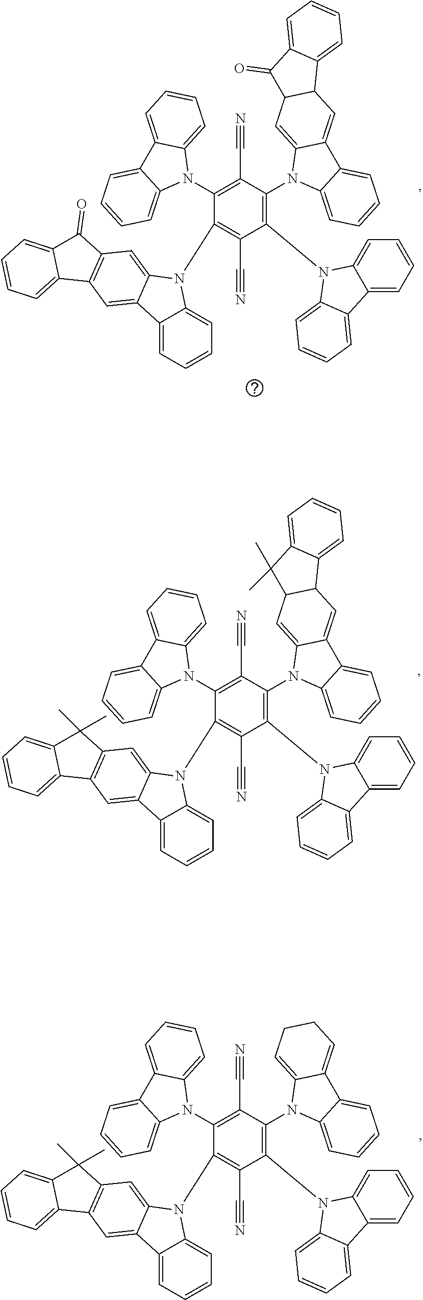 [SMILES: N#Cc1c(-n2c3c(c4ccccc42)=CC2c4ccccc4C(=O)C2C=3)c(-n2c3ccccc3c3ccccc32)c(C#N)c(-n2c3ccccc3c3cc4c(cc32)C(=O)c2ccccc2-4)c1-n1c2ccccc2c2ccccc21 ; CC1(C)c2ccccc2-c2cc3c4ccccc4n(-c4c(C#N)c(-n5c6ccccc6c6ccccc65)c(-n5c6c(c7ccccc75)=CC5c7ccccc7C(C)(C)C5C=6)c(C#N)c4-n4c5ccccc5c5ccccc54)c3cc21 ; CC1(C)c2ccccc2-c2cc3c4ccccc4n(-c4c(C#N)c(-n5c6ccccc6c6ccccc65)c(-n5c6c(c7ccccc75)=CCCC=6)c(C#N)c4-n4c5ccccc5c5ccccc54)c3cc21]

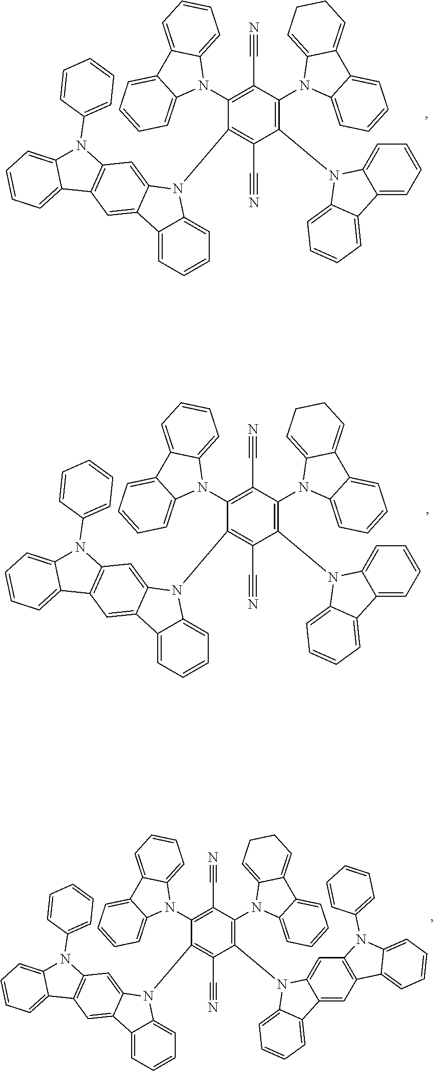 [SMILES: N#Cc1c(-n2c3c(c4ccccc42)=CCCC=3)c(-n2c3ccccc3c3ccccc32)c(C#N)c(-n2c3ccccc3c3cc4c5ccccc5n(-c5ccccc5)c4cc32)c1-n1c2ccccc2c2ccccc21 ; N#Cc1c(-n2c3c(c4ccccc42)=CCCC=3)c(-n2c3ccccc3c3ccccc32)c(C#N)c(-n2c3ccccc3c3cc4c5ccccc5n(-c5ccccc5)c4cc32)c1-n1c2ccccc2c2ccccc21 ; N#Cc1c(-n2c3c(c4ccccc42)=CCCC=3)c(-n2c3ccccc3c3cc4c5ccccc5n(-c5ccccc5)c4cc32)c(C#N)c(-n2c3ccccc3c3cc4c5ccccc5n(-c5ccccc5)c4cc32)c1-n1c2ccccc2c2ccccc21]

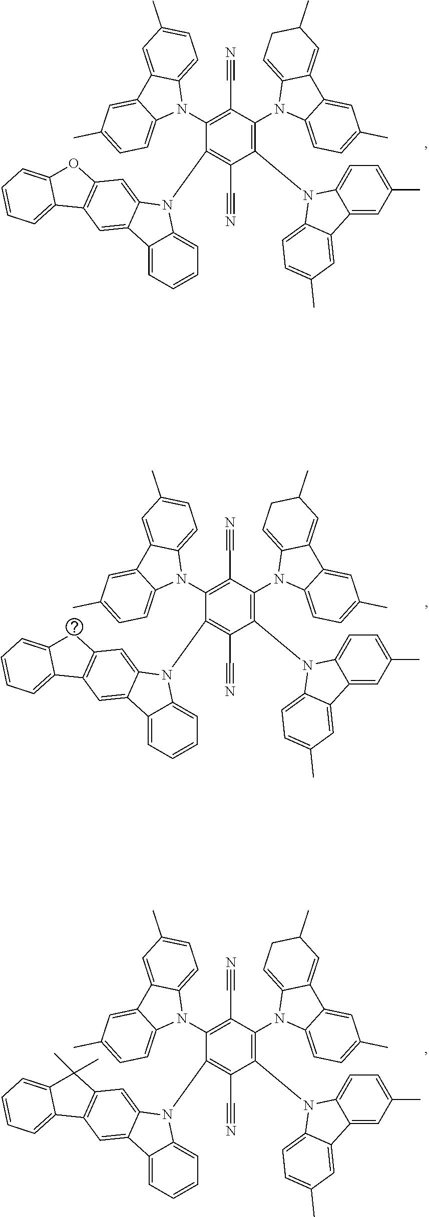 [SMILES: Cc1ccc2c(c1)c1c(n2-c2c(C#N)c(-n3c4ccc(C)cc4c4cc(C)ccc43)c(-n3c4ccccc4c4cc5c(cc43)oc3ccccc35)c(C#N)c2-n2c3ccc(C)cc3c3cc(C)ccc32)=CCC(C)C=1 ; Cc1ccc2c(c1)c1c(n2-c2c(C#N)c(-n3c4ccc(C)cc4c4cc(C)ccc43)c(-n3c4ccccc4c4cc5c(cc43)Cc3ccccc3-5)c(C#N)c2-n2c3ccc(C)cc3c3cc(C)ccc32)=CCC(C)C=1 ; Cc1ccc2c(c1)c1c(n2-c2c(C#N)c(-n3c4ccc(C)cc4c4cc(C)ccc43)c(-n3c4ccccc4c4cc5c(cc43)C(C)(C)c3ccccc3-5)c(C#N)c2-n2c3ccc(C)cc3c3cc(C)ccc32)=CCC(C)C=1]

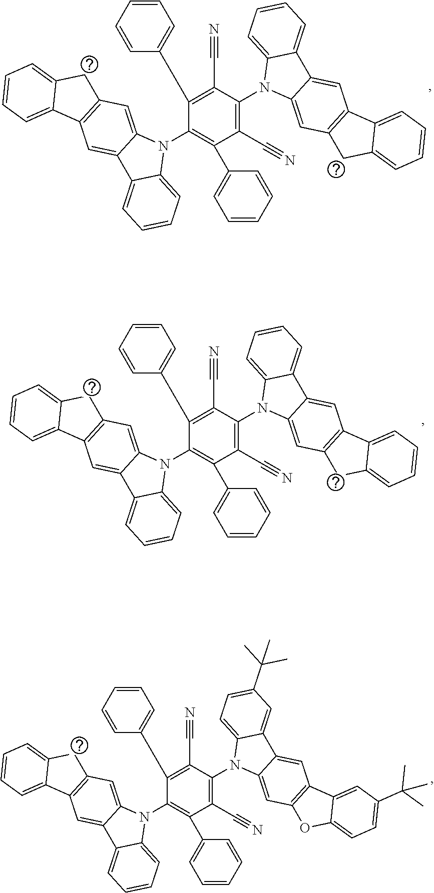 [SMILES: N#Cc1c(-c2ccccc2)c(-n2c3ccccc3c3cc4c(cc32)Cc2ccccc2-4)c(-c2ccccc2)c(C#N)c1-n1c2ccccc2c2cc3c(cc21)Cc1ccccc1-3 ; N#Cc1c(-c2ccccc2)c(-n2c3ccccc3c3cc4c(cc32)Cc2ccccc2-4)c(-c2ccccc2)c(C#N)c1-n1c2ccccc2c2cc3c(cc21)Cc1ccccc1-3 ; CC(C)(C)c1ccc2oc3cc4c(cc3c2c1)c1cc(C(C)(C)C)ccc1n4-c1c(C#N)c(-c2ccccc2)c(-n2c3ccccc3c3cc4c(cc32)Cc2ccccc2-4)c(-c2ccccc2)c1C#N]

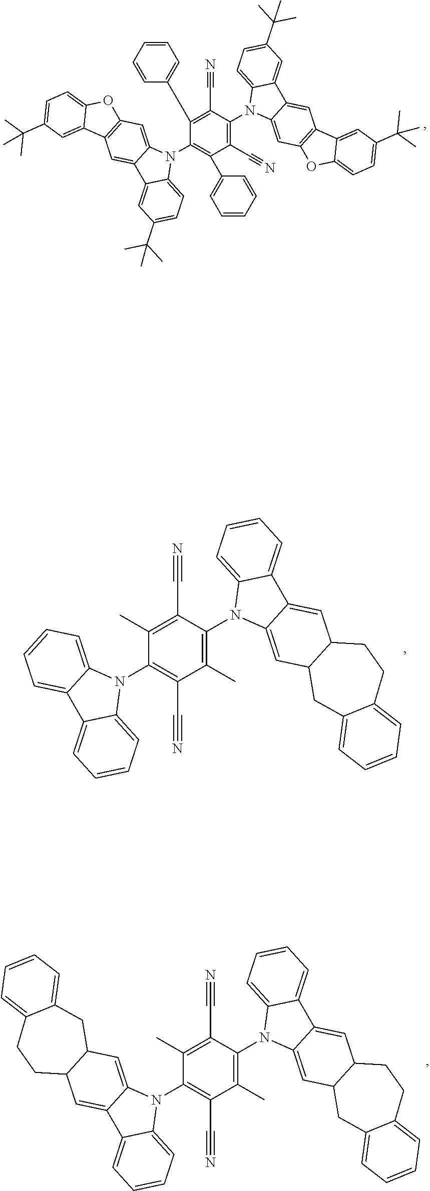 [SMILES: CC(C)(C)c1ccc2oc3cc4c(cc3c2c1)c1cc(C(C)(C)C)ccc1n4-c1c(C#N)c(-c2ccccc2)c(-n2c3ccc(C(C)(C)C)cc3c3cc4c(cc32)oc2ccc(C(C)(C)C)cc24)c(-c2ccccc2)c1C#N ; Cc1c(C#N)c(-n2c3ccccc3c3ccccc32)c(C)c(C#N)c1-n1c2c(c3ccccc31)=CC1CCc3ccccc3CC1C=2 ; Cc1c(C#N)c(-n2c3c(c4ccccc42)=CC2CCc4ccccc4CC2C=3)c(C)c(C#N)c1-n1c2c(c3ccccc31)=CC1CCc3ccccc3CC1C=2]

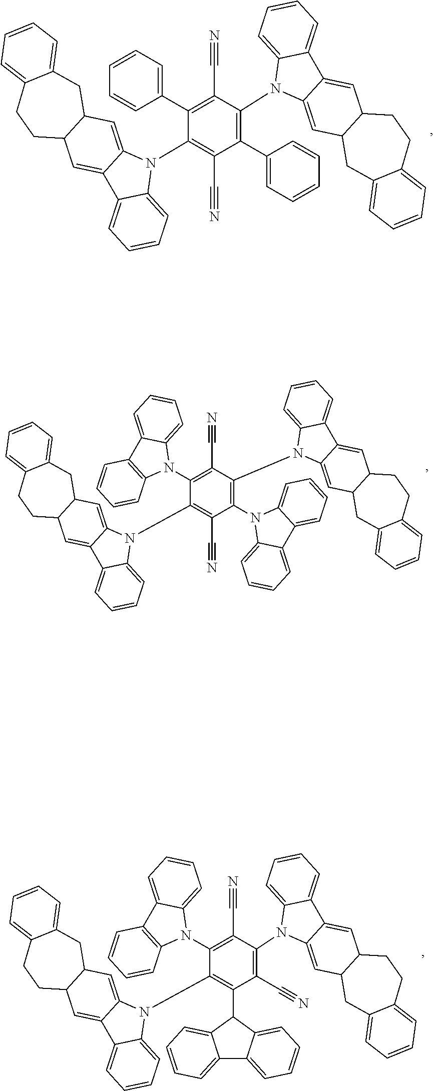 [SMILES: N#Cc1c(-c2ccccc2)c(-n2c3c(c4ccccc42)=CC2CCc4ccccc4CC2C=3)c(C#N)c(-c2ccccc2)c1-n1c2c(c3ccccc31)=CC1CCc3ccccc3CC1C=2 ; N#Cc1c(-n2c3c(c4ccccc42)=CC2CCc4ccccc4CC2C=3)c(-n2c3ccccc3c3ccccc32)c(C#N)c(-n2c3c(c4ccccc42)=CC2CCc4ccccc4CC2C=3)c1-n1c2ccccc2c2ccccc21 ; N#Cc1c(C2c3ccccc3-c3ccccc32)c(-n2c3c(c4ccccc42)=CC2CCc4ccccc4CC2C=3)c(-n2c3ccccc3c3ccccc32)c(C#N)c1-n1c2c(c3ccccc31)=CC1CCc3ccccc3CC1C=2]

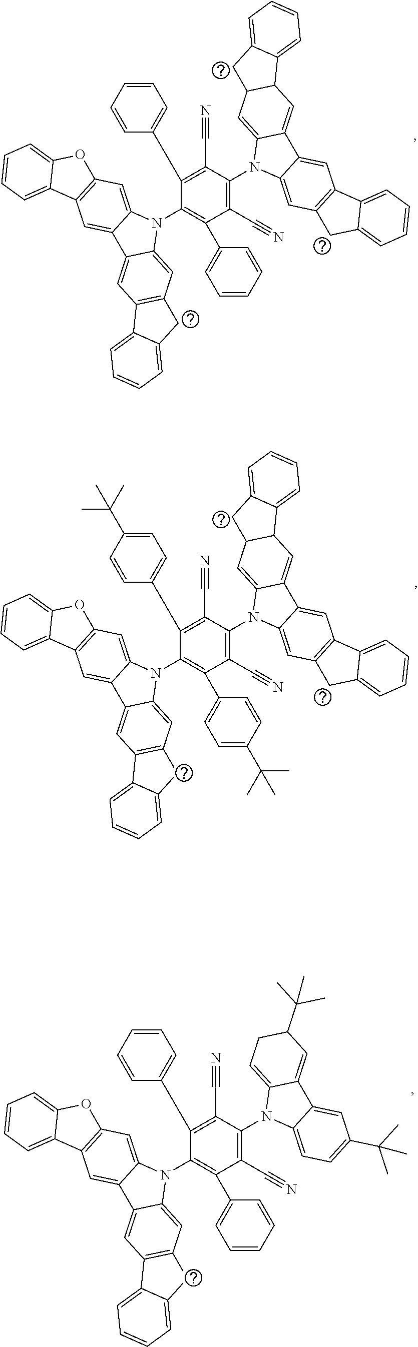 [SMILES: N#Cc1c(-c2ccccc2)c(-n2c3cc4c(cc3c3cc5c(cc32)oc2ccccc25)-c2ccccc2C4)c(-c2ccccc2)c(C#N)c1-n1c2c(c3cc4c(cc31)Cc1ccccc1-4)=CC1c3ccccc3CC1C=2 ; CC(C)(C)c1ccc(-c2c(C#N)c(-n3c4c(c5cc6c(cc53)Cc3ccccc3-6)=CC3c5ccccc5CC3C=4)c(C#N)c(-c3ccc(C(C)(C)C)cc3)c2-n2c3cc4c(cc3c3cc5c(cc32)oc2ccccc25)-c2ccccc2C4)cc1 ; CC(C)(C)c1ccc2c(c1)c1c(n2-c2c(C#N)c(-c3ccccc3)c(-n3c4cc5c(cc4c4cc6c(cc43)oc3ccccc36)-c3ccccc3C5)c(-c3ccccc3)c2C#N)=CCC(C(C)(C)C)C=1]

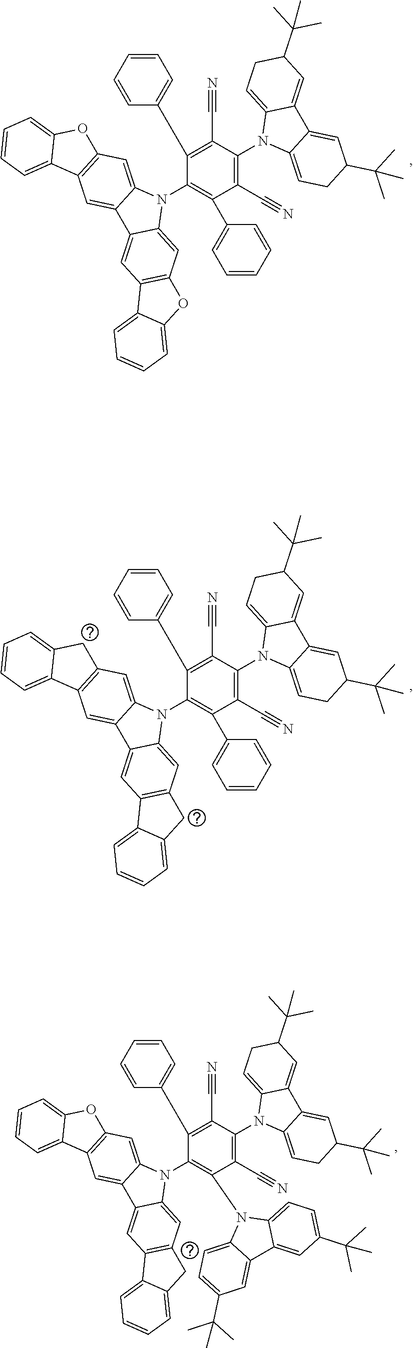 [SMILES: CC(C)(C)C1C=c2c3c(n(-c4c(C#N)c(-c5ccccc5)c(-n5c6cc7oc8ccccc8c7cc6c6cc7c(cc65)oc5ccccc57)c(-c5ccccc5)c4C#N)c2=CC1)=CCC(C(C)(C)C)C=3 ; CC(C)(C)C1C=c2c3c(n(-c4c(C#N)c(-c5ccccc5)c(-n5c6cc7c(cc6c6cc8c(cc65)Cc5ccccc5-8)-c5ccccc5C7)c(-c5ccccc5)c4C#N)c2=CC1)=CCC(C(C)(C)C)C=3 ; CC(C)(C)c1ccc2c(c1)c1cc(C(C)(C)C)ccc1n2-c1c(C#N)c(-n2c3c(c4c2=CCC(C(C)(C)C)C=4)=CC(C(C)(C)C)CC=3)c(C#N)c(-c2ccccc2)c1-n1c2cc3c(cc2c2cc4c(cc21)oc1ccccc14)-c1ccccc1C3]

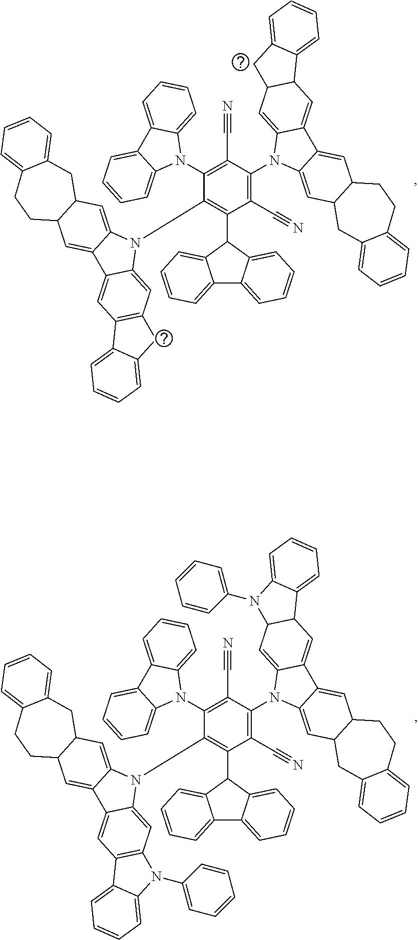 [SMILES: N#Cc1c(C2c3ccccc3-c3ccccc32)c(-n2c3c(c4cc5c(cc42)Cc2ccccc2-5)=CC2CCc4ccccc4CC2C=3)c(-n2c3ccccc3c3ccccc32)c(C#N)c1-n1c2c(c3c1=CC1Cc4ccccc4C1C=3)=CC1CCc3ccccc3CC1C=2 ; N#Cc1c(C2c3ccccc3-c3ccccc32)c(-n2c3c(c4cc5c6ccccc6n(-c6ccccc6)c5cc42)=CC2CCc4ccccc4CC2C=3)c(-n2c3ccccc3c3ccccc32)c(C#N)c1-n1c2c(c3c1=CC1C(C=3)c3ccccc3N1c1ccccc1)=CC1CCc3ccccc3CC1C=2]

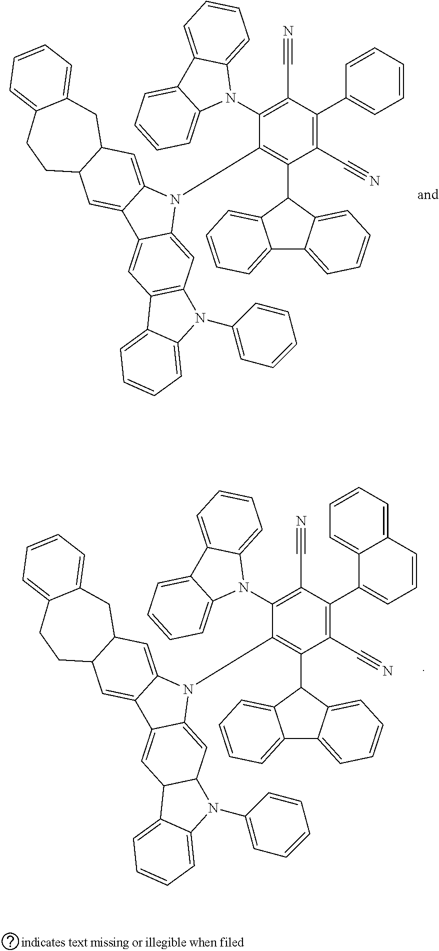 [SMILES: N#Cc1c(-c2ccccc2)c(C#N)c(-n2c3ccccc3c3ccccc32)c(-n2c3c(c4cc5c6ccccc6n(-c6ccccc6)c5cc42)=CC2CCc4ccccc4CC2C=3)c1C1c2ccccc2-c2ccccc21 ; N#Cc1c(-c2cccc3ccccc23)c(C#N)c(-n2c3ccccc3c3ccccc32)c(-n2c3c(c4c2=CC2C(C=4)c4ccccc4N2c2ccccc2)=CC2CCc4ccccc4CC2C=3)c1C1c2ccccc2-c2ccccc21]

An embodiment of the present application further provides a light-emitting device including the above light-emitting layer.

The preparation process of the light-emitting device is not specifically limited here. For example, the light-emitting device may be prepared by vacuum evaporation for each film layer in the light-emitting device.

The type of the light emitting device is not specifically limited here. For example, the light emitting device may include a top-emitting light emitting device or a bottom-emitting light emitting device.

An embodiment of the present application provides a light-emitting device, and a light-emitting layer of the light-emitting device at least includes a first thermally activated delayed fluorescent material, a reverse intersystem crossing rate kRISC of the first thermally activated delayed fluorescent material is large, the energy level difference between the singlet state energy level and the triplet state energy level of the first thermally activated delayed fluorescent material is small, and the smaller the energy level difference between the singlet state and the triplet state, the more conducive to reverse intersystem crossing, so that 75% of the triplet excitons in the first thermally activated delayed fluorescent material may more easily reverse intersystem cross to the singlet state to form singlet excitons, and the formed singlet excitons emit fluorescence when excited. That is, a high proportion of triplet excitons that originally cannot participate in luminescence are converted into singlet excitons that may participate in luminescence, so that the utilization rate of triplet excitons is greatly improved, the luminescence efficiency of the light-emitting layer is effectively improved, the luminescence efficiency and the luminescence performance of the light-emitting device using the above light-emitting layer are improved, and the user experience is good.

In addition, since the first thermally activated delayed fluorescent material has a rigid molecular framework with multiple intermolecular interactions, and the molecular structure may be twisted, it can effectively reduce or even suppress molecular motion and geometric vibration, etc., thereby greatly reducing the non-radiative attenuation caused by concentration quenching, thereby effectively improving the luminous efficiency and luminous performance of the light-emitting device using the above light-emitting layer.

Optionally, as shown in FIG. 1, the light-emitting device further includes an anode 1 and a cathode 3 and a light-emitting layer 2 between the anode 1 and the cathode 3.

The material of the anode is not specifically limited here. For example, the material of the anode may include ITO (Indium Tin Oxides).

The manufacturing process of the anode is not specifically limited here. For example, a glass plate with Ag/ITO may be treated at a vacuum degree of 1×10⁻⁵ Pa and then dried to obtain the anode.

Optionally, the light-emitting device further includes a hole transport layer and an electron transport layer, the hole transport layer is located between the anode and the light-emitting layer; and the electron transport layer is located between the cathode and the light-emitting layer.

The material of the hole transport layer is not specifically limited here. For example, the material of the hole transport layer may include a first thermally activated delayed fluorescent material.

The material of the electron transport layer is not specifically limited here. For example, the material of the electron transport layer may include a first thermally activated delayed fluorescent material.

Optionally, as shown in FIG. 2, the light-emitting device further includes a hole injection layer 4, an electron blocking layer 6, an electron injection layer 7 and a hole blocking layer 9, the hole injection layer 4 is located between the anode 1 and the hole transport layer 5; the electron blocking layer 6 is located between the hole transport layer 5 and the light-emitting layer 2; the electron injection layer 7 is located between the cathode 3 and the electron transport layer 8; and the hole blocking layer 9 is located between the electron transport layer 8 and the light-emitting layer 2.

A material of the electron blocking layer may be any one of mCP, CCP, and Tris-PCz. The Chinese name of mCP is methylcyclopentenolone; the Chinese name of CCP is cyclic citrullinated peptide, and its chemical structure formula is

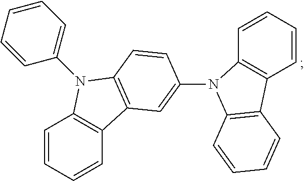 [SMILES: c1ccc(-n2c3ccccc3c3cc(-n4c5ccccc5c5ccccc54)ccc32)cc1]

the Chinese name of Tris-PCz is 9-phenyl-3,6-bis(9-phenyl-9Hcarbazol-3-yl)-9H-carbazole, and its chemical structure formula is

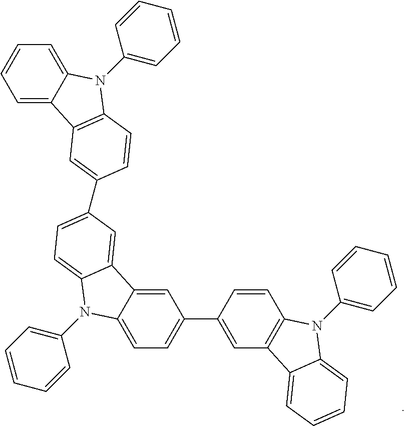 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

A material of the hole blocking layer may be any one of BCP, Bphen and TPBI. The Chinese name of BCP is 2,9-dimethyl-4,7-biphenyl-1,10-phenanthroline; the Chinese name of Bphen is o-phenanthroline; the Chinese name of TPBI is 1,3,5-tri(1-phenyl-1H-benzimidazol-2-yl)benzene, and its chemical structure formula is

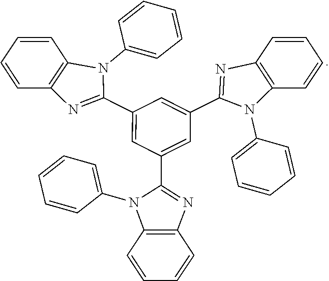 [SMILES: c1ccc(-n2c(-c3cc(-c4nc5ccccc5n4-c4ccccc4)cc(-c4nc5ccccc5n4-c4ccccc4)c3)nc3ccccc32)cc1]

The electron blocking layer may block the electrons in the light-emitting layer from passing through the light-emitting layer, ensuring that more electrons recombine with holes in the light-emitting layer, thereby increasing the number of excitons and further improving the luminous efficiency. The above hole blocking layer may block the holes in the light-emitting layer from passing through the light-emitting layer, ensuring that more holes recombine with electrons in the light-emitting layer, thereby increasing the number of excitons and further improving the luminous efficiency.

A material of the hole injection layer may be any one of MoO₃, F4-TCNQ and HAT-CN. The Chinese name of MoO₃ is molybdenum trioxide; the Chinese name of F4-TCNQ is 2,3,5,6-tetrafluoro-7,7′,8,8′-tetracyanodimethyl-p-benzoquinone; the Chinese name of HAT-CN is 2,3,6,7,10,11-hexacyano-1, 4, 5, 8, 9, 12-hexaazatriphenylene 2, 3, 6, 7, 10, 11, and its chemical structure is

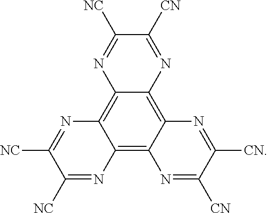 [SMILES: N#Cc1nc2c3nc(C#N)c(C#N)nc3c3nc(C#N)c(C#N)nc3c2nc1C#N]

A material of the electron injection layer may be any one of LiF, Yb, and Liq. Here, the Chinese name of LiF is lithium fluoride; the Chinese name of Yb is ytterbium; the Chinese name of Liq is 8-hydroxyquinoline-lithium, and its chemical structure is

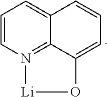

Given below are the molecular excited state information of the first thermally activated delayed fluorescent material F9 (a molecular structure formula:

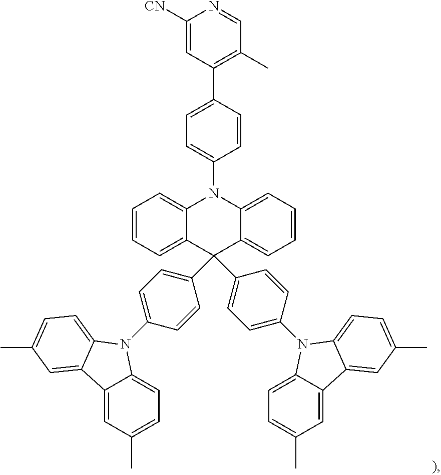

the first thermally activated delayed fluorescent material F10 (a molecular structure formula:

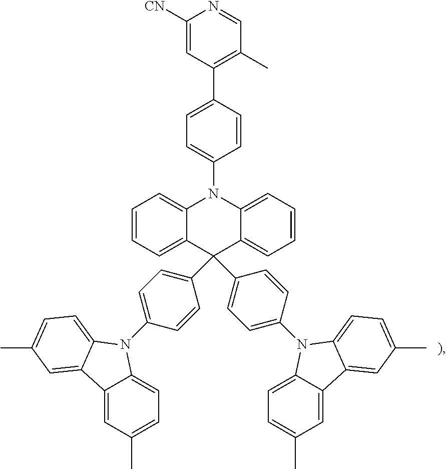

the first thermally activated delayed fluorescent material F12 (a molecular structure formula:

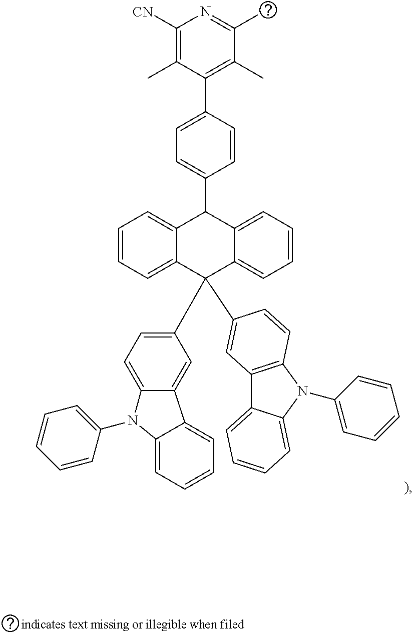

the first compound B4 (a molecular structure formula:

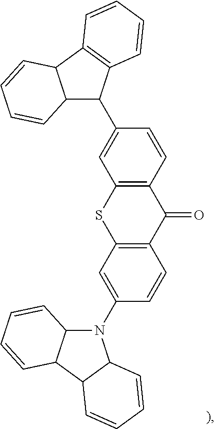 [SMILES: O=c1c2ccc(C3c4ccccc4C4C=CC=CC43)cc2sc2cc(N3C4C=CC=CC4C4C=CC=CC43)ccc12]

the second compound C4 (a molecular structure formula:

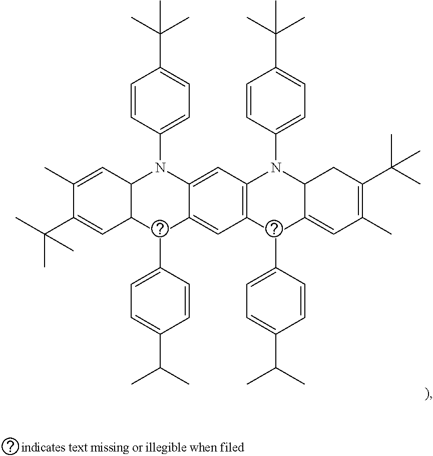 [SMILES: CC1=CC2C(C=C1C(C)(C)C)C(c1ccc(C(C)C)cc1)c1cc3c(cc1N2c1ccc(C(C)(C)C)cc1)N(c1ccc(C(C)(C)C)cc1)C1CC(C(C)(C)C)=C(C)C=C1C3c1ccc(C(C)C)cc1]

the second compound D11 (a molecular structure formula:

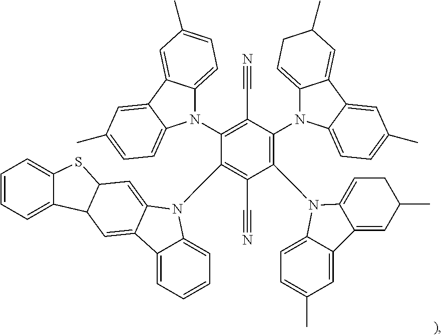 [SMILES: Cc1ccc2c(c1)c1c(n2-c2c(C#N)c(-n3c4c(c5ccccc53)=CC3c5ccccc5SC3C=4)c(-n3c4ccc(C)cc4c4cc(C)ccc43)c(C#N)c2-n2c3c(c4cc(C)ccc42)=CC(C)CC=3)=CCC(C)C=1]

the second compound E5 (a molecular structure formula:

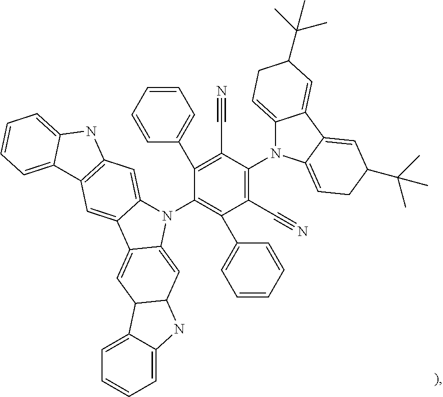 [SMILES: CC(C)(C)C1C=c2c3c(n(-c4c(C#N)c(-c5ccccc5)c(-n5c6c(c7cc8c(cc75)[nH]c5ccccc58)=CC5c7ccccc7NC5C=6)c(-c5ccccc5)c4C#N)c2=CC1)=CCC(C(C)(C)C)C=3]

and the comparative example D (a molecular structure formula:

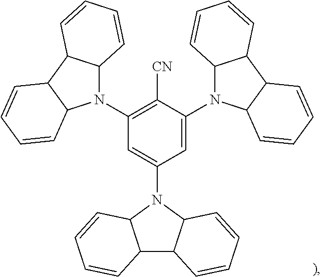 [SMILES: N#Cc1c(N2C3C=CC=CC3C3C=CC=CC32)cc(N2C3C=CC=CC3C3C=CC=CC32)cc1N1C2C=CC=CC2C2C=CC=CC21]

shown in Table 1 below.

TABLE 1

| | T1 | S1 | λ RISC | kRISC |
|---|---|---|---|---|
| Material | (eV) | (eV) | (eV) | (s⁻¹) |
| F9 | 2.78 | 2.90 | — | 5.0 × 10⁵ |
| F10 | 2.79 | 2.88 | — | 7.5 × 10⁶ |
| F12 | 2.80 | 2.98 | — | 6.7 × 10⁶ |
| B4 | 2.61 | 2.63 | 0.025 | 6.2 × 10⁷ |
| C4 | 2.40 | 2.37 | — | — |
| D11 | 2.37 | 2.36 | — | — |
| E5 | 2.77 | 2.76 | — | — |
| D | 2.59 | 2.69 | 0.28 | 3.0 × 10³ |

Each of compounds is applied to light-emitting devices respectively to obtain the following light-emitting devices.

A specific embodiment 1 of the present application is provided below. The light-emitting device includes: an anode with a material of AW ITO and a thickness of 90/10 nm; a hole injection layer on the anode; a hole transport layer on the hole injection layer; a light-emitting layer on the hole transport layer, a material which is a first thermally activated delayed fluorescent material (a molecular structure formula is

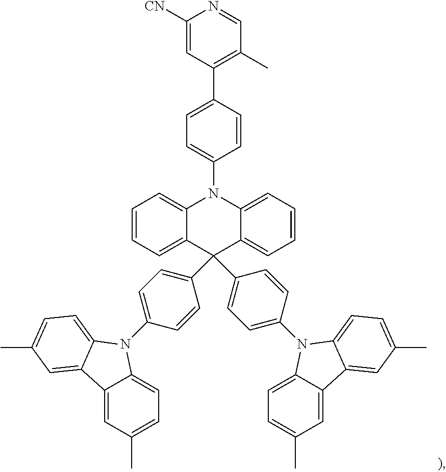

and the thickness is 30 nm; an electron transport layer on the light-emitting layer; an electron injection layer on the electron transport layer, which is made of Liq and has a thickness of 1 nm; a cathode located on the electron injection layer, which is made of Mg:Al (ratio is 9:1) and has a thickness of 15 nm; and a capping layer on the cathode, which has a thickness of 60 nm.

A specific embodiment 2 of the present application is provided below. The light-emitting device includes: an anode, which is made of Ag/ITO and has a thickness of 90/10 nm; a hole injection layer on the anode; a hole transport layer on the hole injection layer; a light-emitting layer on the hole transport layer, which is made of a first thermally activated delayed fluorescent material (a molecular structure formula is

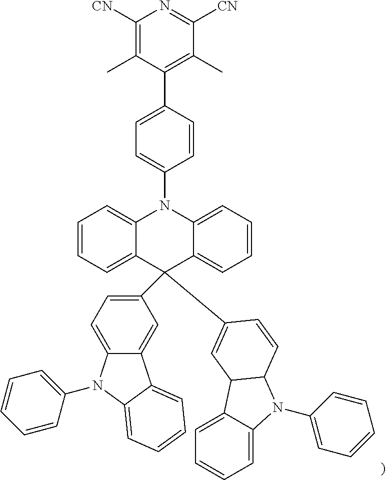

and has a thickness of 30 nm; an electron transport layer on the light-emitting layer: an electron injection layer located on the electron transport layer, which is made of Liq and has a thickness of 1 nm; a cathode on the electron injection layer, which is made of Mg:Al (ratio is 9:1) and has a thickness of 15 nm; and a capping layer on the cathode, which has a thickness is 6 nm.

The specific embodiment 3 of the present application is provided below. The light-emitting device includes: an anode, which is made of Ag/ITO and has a thickness of 90/10 nm; a hole injection layer on the anode; a hole transport layer on the hole injection layer; a light-emitting layer on the hole transport layer, which is made of a first thermally activated delayed fluorescent material (molecular structure formulas is

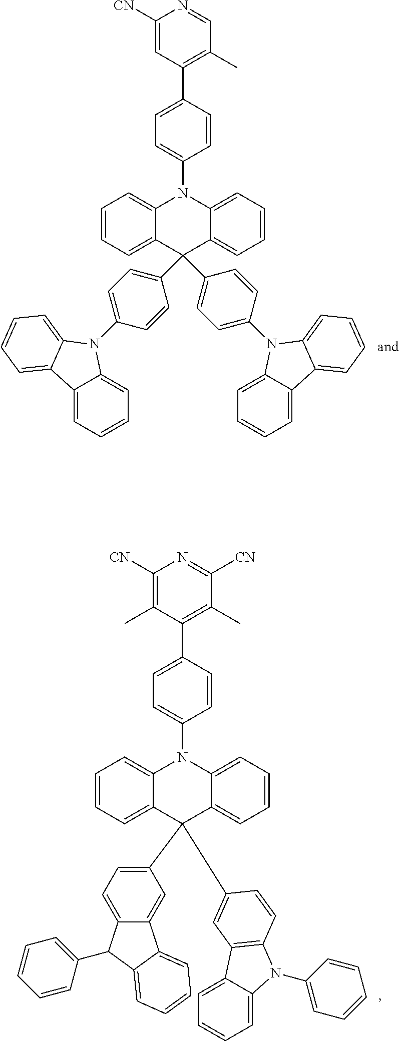

concentration is each 50%) which has a thickness of 30 nm; an electron transport layer on the light-emitting layer; an electron injection layer on the electron transport layer, which is made of is Liq, and has a thickness of 1 nm; a cathode on the electron injection layer, which is made of Mg:Al (a ratio is 9:1), and has a thickness of 15 nm; and a capping layer on the cathode, which has a thickness of 60 nm.

A specific embodiment 4 of the present application is provided below. The light-emitting device includes: an anode, which is made of Ag/ITO, and has a thickness of 90/10 nm; a hole injection layer on the anode; a hole transport layer on the hole injection layer; a light-emitting layer on the hole transport layer, which is made of a first thermally activated delayed fluorescent material (a molecular structure formula is

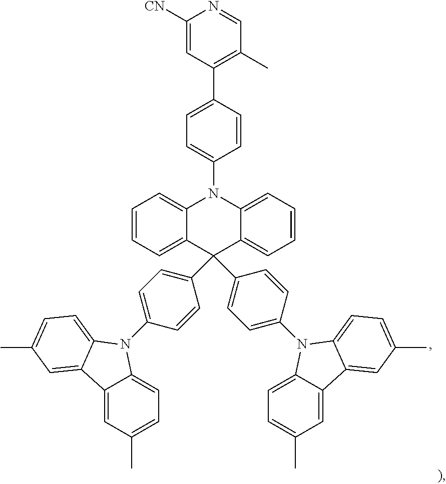

which has a concentration of 97%, and whose guest material is a first compound (a molecular structure formula is

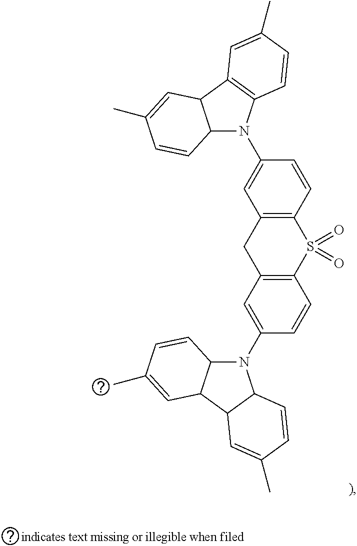 [SMILES: CC1=CC2c3cc(C)ccc3N(c3ccc4c(c3)Cc3cc(N5C6C=CC(C)=CC6C6C=C(C)C=CC65)ccc3S4(=O)=O)C2C=C1]

which has a concentration of 3% and has a thickness is 30 nm; an electron transport layer on the light-emitting layer; an electron injection layer on the electron transport layer, which is made of Liq and has a thickness of 1 nm; a cathode on the electron injection layer, which is made of Mg:Al (a ratio is 9:1), and has a thickness of 15 nm; and a capping layer on the cathode, which has a thickness is 60 nm.

A specific embodiment 5 of the present application is provided below. The light-emitting device includes: an anode, which is made of Ag/ITO, and has a thickness of 90/10 nm; a hole injection layer on the anode; a hole transport layer on the hole injection layer; a light-emitting layer on the hole transport layer, whose main material is a first thermally activated delayed fluorescent material (a molecular structure formula is

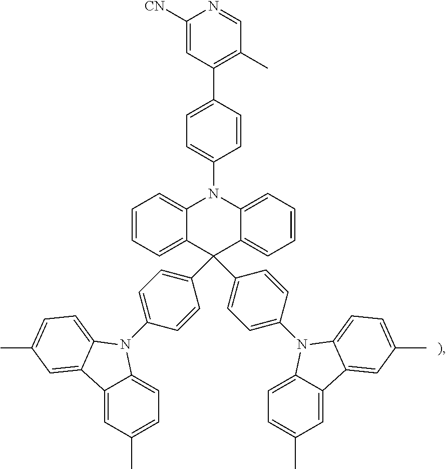

which has a concentration of 99%, and whose guest material is a second compound (a molecular structure formula is

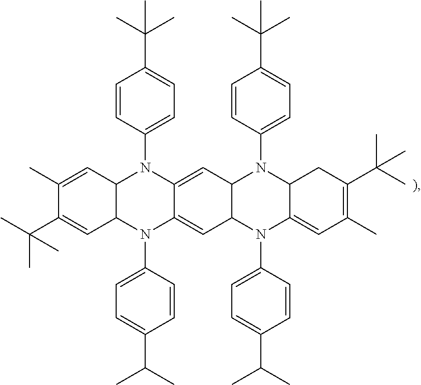 [SMILES: CC1=CC2C(C=C1C(C)(C)C)N(c1ccc(C(C)C)cc1)C1=CC3C(C=C1N2c1ccc(C(C)(C)C)cc1)N(c1ccc(C(C)(C)C)cc1)C1CC(C(C)(C)C)=C(C)C=C1N3c1ccc(C(C)C)cc1]

which has a concentration of 1% and a thickness is 30 nm; an electron transport layer on the light-emitting layer; an electron injection layer on the electron transport layer, which is made of Liq, and has a thickness of 1 nm; a cathode on the electron injection layer, which is made of Mg:Al (a ratio is 9:1), and has a thickness of 15 nm; and a capping layer on the cathode, which has a thickness of 60 nm.

A specific embodiment 6 of the present application is provided below. The light-emitting device includes: an anode, which is made of Ag/ITO, and has a thickness of 90/10 nm; a hole injection layer on the anode; a hole transport layer on the hole injection layer; a light-emitting layer on the hole transport layer, whose main material is a first thermally activated delayed fluorescent material (a molecular structure formula is

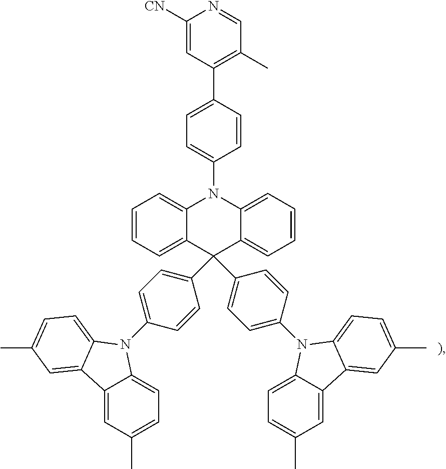

which has a concentration of 90%, and whose guest material is a second compound (a molecular structure formula is

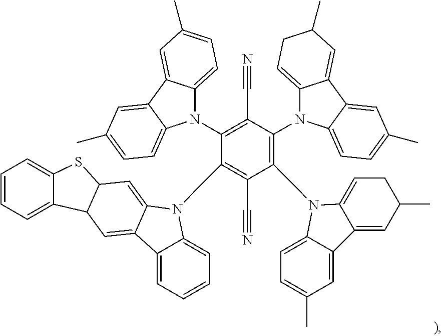 [SMILES: Cc1ccc2c(c1)c1c(n2-c2c(C#N)c(-n3c4c(c5ccccc53)=CC3c5ccccc5SC3C=4)c(-n3c4ccc(C)cc4c4cc(C)ccc43)c(C#N)c2-n2c3c(c4cc(C)ccc42)=CC(C)CC=3)=CCC(C)C=1]

which has a concentration of 10%, and has a thickness of 30 nm; an electron transport layer on the light-emitting layer; an electron injection layer on the electron transport layer, which is made of Liq, and has a thickness of 1 nm; a cathode on the electron injection layer, which is made of Mg:Al (a ratio is 9:1), and has a thickness of 15 nm; and a capping layer on the cathode, which has a thickness of 60 nm.

A specific embodiment 7 of the present application is provided below. The light-emitting device includes: an anode, which is made of Ag/ITO, and has a thickness of 90/10 nm; a hole injection layer on the anode; a hole transport layer on the hole injection layer; a light-emitting layer on the hole transport layer, whose main material is a first thermally activated delayed fluorescent material (a molecular structure formula is

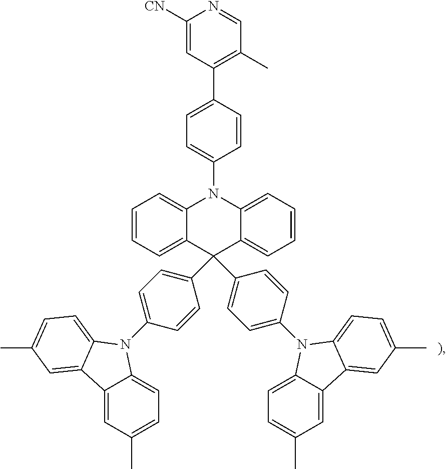

which has a concentration of 90%, and whose guest material is a second compound (a molecular structure formula is

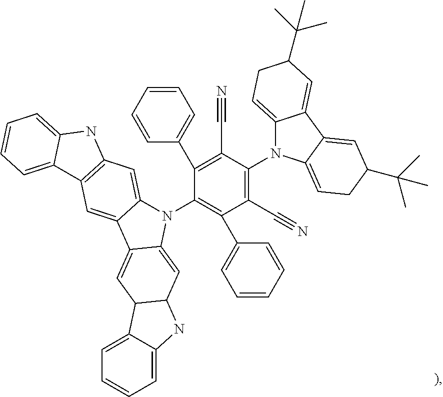 [SMILES: CC(C)(C)C1C=c2c3c(n(-c4c(C#N)c(-c5ccccc5)c(-n5c6c(c7cc8c(cc75)[nH]c5ccccc58)=CC5c7ccccc7NC5C=6)c(-c5ccccc5)c4C#N)c2=CC1)=CCC(C(C)(C)C)C=3]

which has a concentration of 10%, and has a thickness of 30 nm; an electron transport layer located on the light-emitting layer; an electron injection layer located on the electron transport layer, whose material is Liq, and whose thickness is 1 nm; a cathode on the electron injection layer, which is made of Mg:Al (a ratio is 9:1), and has a thickness of 15 nm; and a capping layer on the cathode, which has a thickness of 60 nm.

A comparative example 1 of the present application is provided below. The light-emitting device includes: an anode, which is made of Ag/ITO and has a thickness of 90/10 nm; a hole injection layer on the anode; a hole transport layer on the hole injection layer; a light-emitting layer on the hole transport layer, whose material has a molecular structure formula of

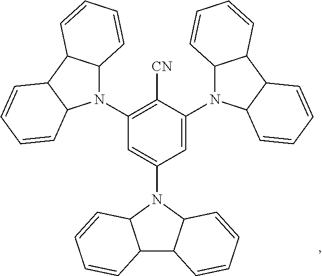 [SMILES: N#Cc1c(N2C3C=CC=CC3C3C=CC=CC32)cc(N2C3C=CC=CC3C3C=CC=CC32)cc1N1C2C=CC=CC2C2C=CC=CC21]

and has a thickness of 30 nm; an electron transport layer on the light-emitting layer; an electron injection layer on the electron transport layer, which is made of Liq and has a thickness of 1 nm; a cathode on the electron injection layer, which is made of Mg:Al (a ratio is 9:1) and has a thickness of 15 nm; and a capping layer on the cathode, which has a thickness of 60 nm.

A comparative example 2 of the present application is provided below. The light-emitting device includes: an anode with a material of Ag/ITO and a thickness of 90/10 nm; a hole injection layer on the anode; a hole transport layer on the hole injection layer; a light-emitting layer on the hole transport layer, the host material of which is a first thermally activated delayed fluorescent material (a molecular structure formula is

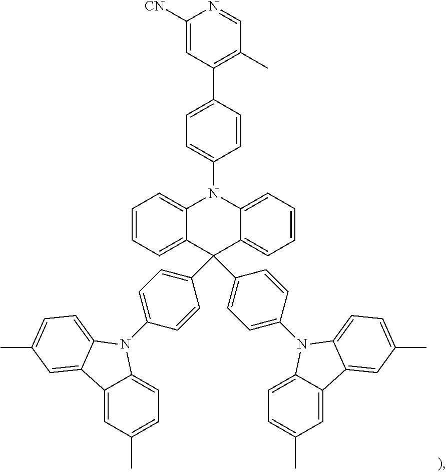

which has a concentration of 97%, and whose guest material has a molecular structure formula of

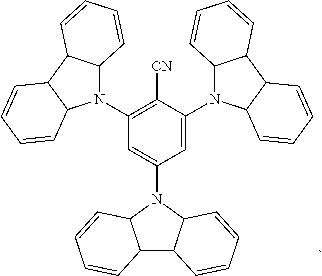 [SMILES: N#Cc1c(N2C3C=CC=CC3C3C=CC=CC32)cc(N2C3C=CC=CC3C3C=CC=CC32)cc1N1C2C=CC=CC2C2C=CC=CC21]

which has a concentration of 3%, and has a thickness of 30 nm: an electron transport layer on the light-emitting layer; an electron injection layer on the electron transport layer, which is made of Liq and has a thickness of 1 nm; a cathode on the electron injection layer, which is made of Mg:Al (a ratio is 9:1) and has a thickness of 15 nm; and a capping layer on the cathode, which has a thickness of 60 nm.

The above light-emitting devices are tested, and the performance of the light-emitting devices was shown in Table 2 below.

TABLE 2

| Light-emitting | Current density | Voltage | Efficiency |
|---|---|---|---|
| device | (mA/cm²) | (V) | (cd/A) |
| Example 1 | 10 | 8.7 | 31 |
| Example 2 | 10 | 4.6 | 62 |
| Example 3 | 10 | 4.1 | 81 |
| Example 4 | 10 | 3.9 | 110 |
| Example 5 | 10 | 3.9 | 56 |
| Example 6 | 10 | 3.9 | 42 |
| Comparative | 10 | 6.3 | 11.2 |
| Example 1 | | | |
| Comparative | 10 | 4.2 | 19 |
| Example 2 | | | |

It can be seen from the above table 2 that comparing the example 1 with the comparative example 1, the material F10 of the present application is more suitable as an undoped luminescent material than the material D.

Comparing examples 3-5 with the comparative example 2, the material of the present application is more suitable as the luminescent material of the luminescent layer than the material D.

The material F10 of the present application is suitable as a single host material, or being doped with other guest materials as a host material.

The above light-emitting device may be applied to a display apparatus, and the specific structure of the display apparatus is not limited here.

For example, the display apparatus may include a display substrate and a light-emitting device. The display substrate includes a plurality of pixel units arranged in an array, and the light emitting device includes a red light emitting device, a green light emitting device, and a blue light emitting device arranged in an array. Each pixel unit includes a red sub-pixel, a green sub-pixel, and a blue sub-pixel, the red sub-pixel is electrically connected to the red light-emitting device, the green sub-pixel is electrically connected to the green light-emitting device, and the blue sub-pixel is electrically connected to the blue light-emitting device.

As shown in FIG. 3, the red sub-pixel is electrically connected to the red light-emitting device 100, the green sub-pixel is electrically connected to the green light-emitting device 200, and the blue sub-pixel is electrically connected to the blue light-emitting device 300. As shown in FIG. 3, the red sub-pixel located at the leftmost end is taken as an example to illustrate the specific structure. The red sub-pixel includes a buffer layer 11, an active layer 210, a gate insulating layer 12, a gate metal layer (including a gate 11 and a first electrode 212), an insulating layer 13, an electrode layer (including a second electrode 213), an interlayer dielectric layer 14, a source-drain metal layer (including a source electrode 111 and a drain electrode 112), a flat layer 15 and a pixel defining layer 302, which are stacked in sequence on the substrate 10. The first electrode 212 and the second electrode 213 are configured to form a storage capacitor. The pixel defining layer 302 includes an opening, and a red light-emitting device 100 is arranged in the opening. An anode 1 of the red light-emitting device 100 is electrically connected to the drain electrode 112 of the thin film transistor. The display substrate further includes a spacer 34 located on the pixel defining layer 302. It should be noted that, in the display substrate, spacers may be provided on part of the pixel defining layer or on all of the pixel defining layer, which is not limited here.

The red light-emitting device 100 includes an anode 1, a hole injection layer 4, a hole transport layer 5, an electron blocking layer 6, a red light-emitting layer 113, a hole blocking layer 9, an electron transport layer 8, an electron injection layer 7 and a cathode 3 which are stacked in this order on the anode 1.

It should be noted that the light-emitting layers of the green light-emitting device 200 and the blue light-emitting device 300 shown in FIG. 3 are different in materials from the light-emitting layer of the red light-emitting device 100. The light-emitting layer of the green light-emitting device is configured to emit green light, the light-emitting layer of the blue light-emitting device is configure to emit blue light, and the light-emitting layer of the red light-emitting device is configure to emit red light. In addition, the electron blocking layers of the green light-emitting device and the blue light-emitting device are different in materials from the electron blocking layer of the red light-emitting device. Except for the light-emitting layer and the electron blocking layer, other film layers included in the green light-emitting device and the blue light-emitting device are the same as those included in the red light-emitting device, and will not be described in detail here.

As shown in FIG. 3, the display device may further include a first inorganic layer 421, an organic layer 43, and a second inorganic layer 422 covering the light-emitting device. The first inorganic layer 421, the organic layer 43 and the second inorganic layer 422 may play a packaging role, protect the light-emitting device, and extend its service life.

An embodiment of the present application further provides a display apparatus including the above light-emitting device.

The above display apparatus may be a flexible display device (also called a flexible screen) or a rigid display device (i.e., a display screen that may not be bent), which is not limited here. The above display device may be an OLED display device or an LCD (Liquid Crystal Display) display device. The above display device may be any product or component with a display function, such as a television, a digital camera, a mobile phone, a tablet computer, etc. The above display device may also be applied to the fields of identity recognition, medical equipment, etc. Products that have been promoted or have good promotion prospects include security identity authentication, intelligent door locks, medical image acquisition, etc. The display device has the advantages of high luminous efficiency, good display effect, long service life, high stability, high contrast, good imaging quality and high product quality.

The description provided herein describes many concrete details. However, it can be understood that the embodiments of the present disclosure may be implemented without those concrete details. In some of the embodiments, well-known processes, structures and techniques are not described in detail, so as not to affect the understanding of the description.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A light-emitting layer, comprising at least:
a first thermally activated delayed fluorescent material, wherein a reverse intersystem crossing rate kRISC1 of the first thermally activated delayed fluorescent material satisfies: kRISC1>1.0×10⁴ s⁻¹, a photoluminescence quantum yield PLQY of the first thermally activated delayed fluorescent material in a pure film state satisfies: PLQY≥50%, and a horizontal dipole ratio θ// of the first thermally activated delayed fluorescent material satisfies: θ//>67%.

2. The light-emitting layer according to claim 1, wherein an energy level difference ΔEST1 between a singlet state energy level and a triplet state energy level of the first thermally activated delayed fluorescent material satisfies: ΔEST1≤0.15 eV.

3. The light-emitting layer according to claim 2, wherein a general structure formula of the first thermally activated delayed fluorescent material is: 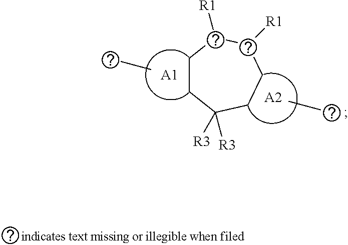
wherein R1-R3 are each independently any one of hydrogen, deuterium, fluorine, chlorine, bromine, iodine, CN, Si(R6)₃, a straight chain alkyl group, an alkoxyl group, a thioalkyl group with 1-40 carbon atoms, a branched chain with 3-40 carbon atoms, a cyclic alkyl group with 3-40 carbon atoms, an alkoxyl group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, and a heteroaralkyl group with 5-60 aromatic rings; R1-R3 may each independently be substituted with one or more R4, R4 is any one of hydrogen, a straight chain alkyl group with 1-22 carbon atoms, an alkoxyl group with 1-22 carbon atoms, a branched chain with 3-22 carbon atoms, a cyclic alkyl group with 3-22 carbon atoms and an alkoxyl group with 3-22 carbon atoms; one or more non-adjacent carbon atoms in R4 may be substituted with any one of oxygen, sulfur, SO, SO₂, CO, O—CO—O, CO—O, —CH═CH— and —C≡C; one or more hydrogen atoms in R4 may be substituted with any one of fluorine, chlorine, bromine, iodine, CN, an aryl group with 5-40 carbon atoms, a heteroaryl group with 5-40 carbon atoms, an aryloxy group with 5-40 carbon atoms, a heteroaryloxy group with 5-40 carbon atoms, and a non-aromatic group; one or more non-adjacent CH₂ in R1-R3 may each independently substituted with any one of Si(R6)₂, C═NR6, P(═O)(R6), SO, SO₂, NR6, oxygen, sulfur, and CONR6; and one or more hydrogen atoms in R1-R3 may each independently be substituted with any one of deuterium, fluorine, chlorine, bromine, and iodine;
two or more adjacent R1-R3 form any one of a monocyclic aliphatic ring and a polycyclic aliphatic ring, which may be substituted with R4;
at least one of R2 and R3 is not hydrogen;
R1 is substituted with at least one cyano group, R1 contains t nitrogen atoms, and t is any one of 1, 2 and 3;
A1 and A2 are each independently any one of an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, and a heteroaralkyl group with 5-60 aromatic rings, and A1 and A2 may each independently be substituted with one or more R4;
m and n are each independently any one of 0, 1, 2, 3 and 4; and
p and q are each independently 0 or 1, and p+q≠0.

4. The light-emitting layer according to claim 3, wherein the first thermally activated delayed fluorescent material comprises diphenylpyridine or nitrogen-containing diphenylpyridine.

5. The light-emitting layer according to claim 4, wherein when the first thermally activated delayed fluorescent material comprises the nitrogen-containing diphenylpyridine, a general structure formula of the first thermally activated delayed fluorescent material is any one of:

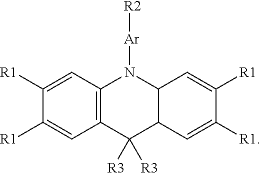

6. The light-emitting layer according claim 3, wherein R3 is selected from any one of:

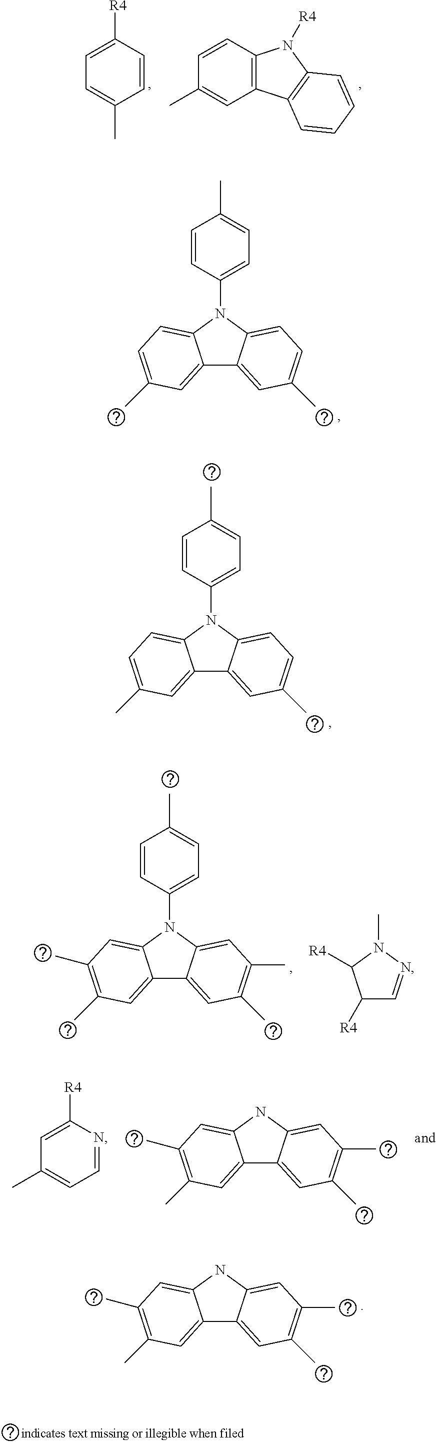

7. The light-emitting layer according to claim 6, wherein a chemical structure formula of the first thermally activated delayed fluorescent material comprises any one of:

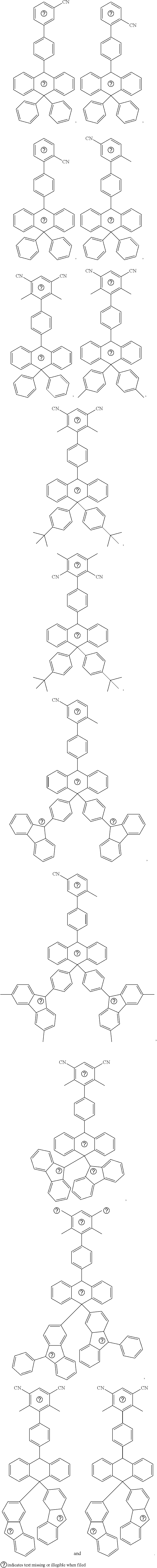

8. The light-emitting layer according to claim 1, wherein the light-emitting layer further comprises a first compound doped in the first thermally activated delayed fluorescent material; and
an absolute value of a difference between reorganization energy λRISC of the first compound and an energy level difference ΔEST2 between a singlet state energy level and a triplet state energy level of the first compound satisfies: |λRISC-ΔEST2|≤0.1 eV.

9. The light-emitting layer according to claim 8, wherein the first compound is a second thermally activated delayed fluorescent material; and
a reverse intersystem crossing rate kRISC2 of the first compound satisfies: kRISC2>1.0×10⁴ s⁻¹.

10. The light-emitting layer according to claim 8, wherein a general structure formula of the first compound is: 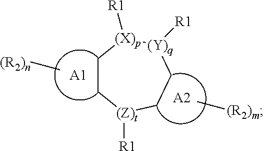
wherein X, Y and Z are each independently any one of carbon, nitrogen, BR3, C(R3)₂, —C(R3)₂—C(R3)₂—, —C(R3)₂—O—, —C(R3)₂—S—, —R3C═CR3-, —R3C═N—, Si(R3)₂, —Si(R3)₂, —Si(R3)₂—, C═O, oxygen, sulfur, S═O, SO₂, NR3, PR3, and P(═O)R3;
R1 is any one of hydrogen, deuterium, fluorine, chlorine, bromine, iodine, CN, Si(R6)₃, a straight chain alkyl group, an alkoxy group, a thioalkyl group with 1-40 carbon atoms, a branched chain with 3-40 carbon atoms, a cyclic alkyl group with 3-40 carbon atoms, an alkoxy group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, and a heteroaryloxy group with 5-60 aromatic rings, an aralkyl group with 5-60 aromatic rings, and a heteroaralkyl group with 5-60 aromatic rings; R1 may be substituted with one or more R4, R4 is any one of hydrogen, a straight chain alkyl group with 1-22 carbon atoms, an alkoxy chain with 1-22 carbon atoms, a branched chain with 3-22 carbon atoms, a cyclic alkyl group with 3-22 carbon atoms, and an alkoxy chain with 3-22 carbon atoms; one or more non-adjacent carbon atoms in R4 may be substituted with any one of oxygen, sulfur, SO, SO₂, CO, O—CO—O, CO—O, —CH═CH— and —C≡C; one or more hydrogen atoms in R4 may be substituted with any one of fluorine, chlorine, bromine, iodine, CN, an aryl group with 5-40 carbon atoms, a heteroaryl group with 5-40 carbon atoms, an aryloxy group with 5-40 carbon atoms, a heteroaryloxy group with 5-40 carbon atoms and a non-aromatic group; one or more non-adjacent CH₂ in R1 may be substituted with any one of Si(R6)₂, C═NR6, P(═O)(R6), SO, SO₂, NR6, oxygen, sulfur and CONR6; and one or more hydrogen atoms in R1 may be substituted with any one of deuterium, fluorine, chlorine, bromine and iodine;
two or more adjacent R1 form any one of a monocyclic aliphatic ring and a polycyclic aliphatic ring, which may be substituted with R4;
A1 and A2 are each independently any one of an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, and a heteroaralkyl group with 5-60 aromatic rings; and A1 and A2 may each independently be substituted with one or more R4;
p, q and t are each independently 0 or 1, and p+q≠0; and
m and n are each independently any one of 0, 1, 2, 3 and 4.

11. The light-emitting layer according to claim 10, wherein the first compound comprises a first electron-donating group, a first electron-accepting group and a first linking group, the first electron-donating group is bonded to the first electron-accepting group through the first linking group, and the first linking group comprises a benzene ring or pyridine.

12. The light-emitting layer according to claim 11, wherein a chemical structure formula of the first compound comprises any one of:

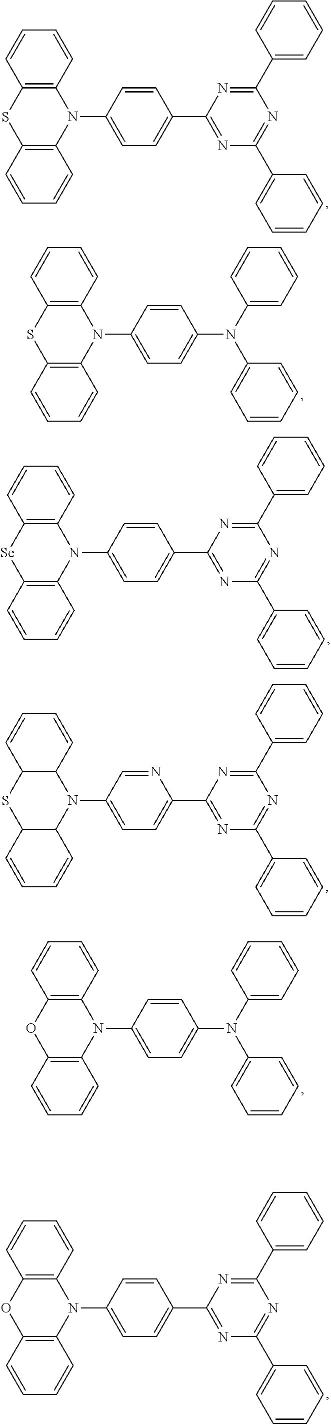

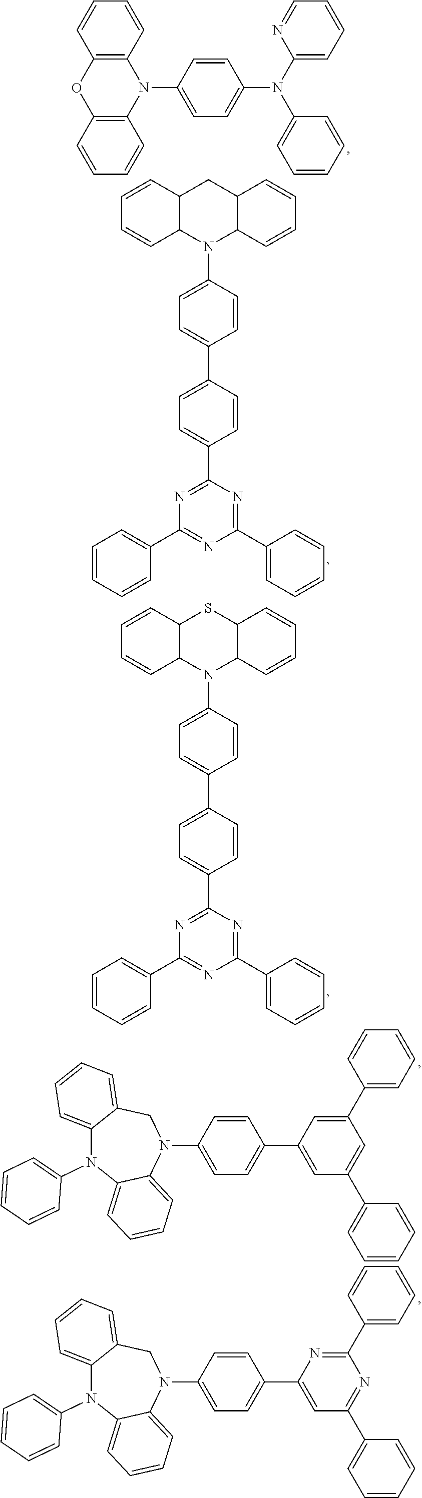

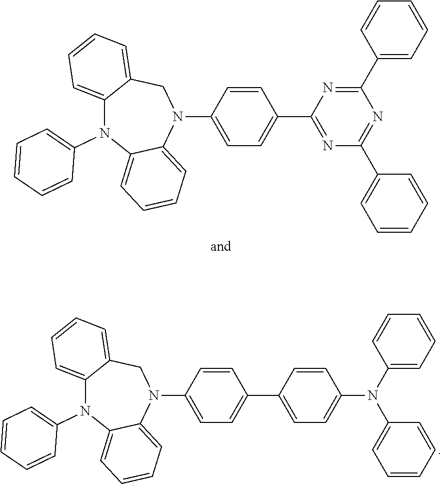 [SMILES: c1ccc(-c2nc(-c3ccccc3)nc(-c3ccc(N4Cc5ccccc5N(c5ccccc5)c5ccccc54)cc3)n2)cc1 ; c1ccc(N(c2ccccc2)c2ccc(-c3ccc(N4Cc5ccccc5N(c5ccccc5)c5ccccc54)cc3)cc2)cc1]

13. The light-emitting layer according to claim 10, wherein the first compound comprises a second electron-donating group, a third electron-donating group and a second electron-accepting group, and the second electron-donating group is bonded to the third electron-donating group through the second electron-accepting group.

14. The light-emitting layer according to claim 13, wherein a chemical structure formula of the first compound comprises any one of:

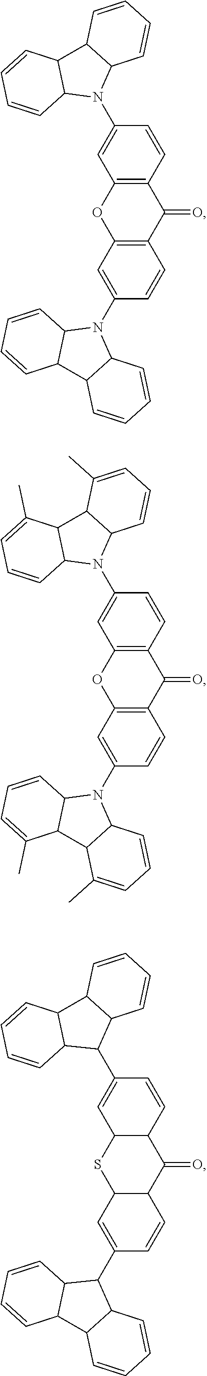

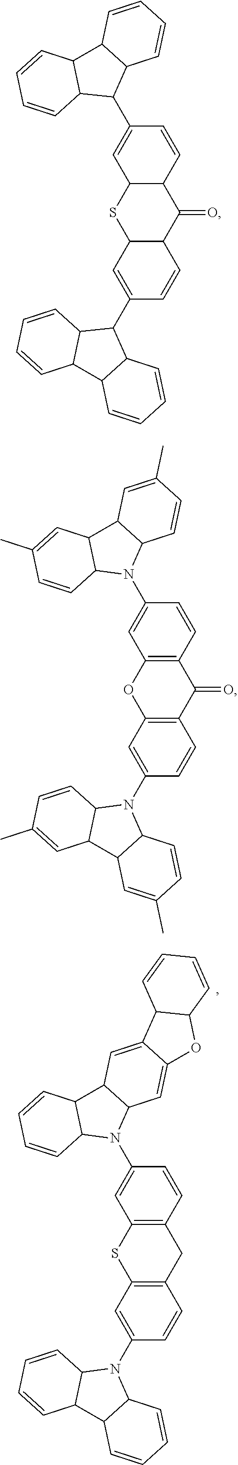

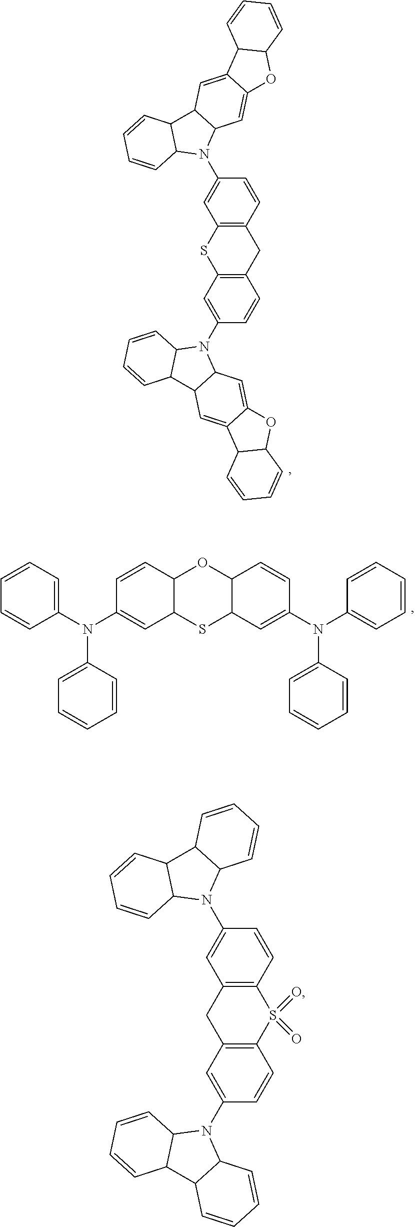 [SMILES: C1=CC2OC3=CC4C(C=C3C2C=C1)C1C=CC=CC1N4c1ccc2c(c1)Sc1cc(N3C4C=CC=CC4C4C=C5C(=CC43)OC3C=CC=CC53)ccc1C2 ; C1=CC2OC3C=CC(N(c4ccccc4)c4ccccc4)=CC3SC2C=C1N(c1ccccc1)c1ccccc1 ; O=S1(=O)c2ccc(N3C4C=CC=CC4C4C=CC=CC43)cc2Cc2cc(N3C4C=CC=CC4C4C=CC=CC43)ccc21]

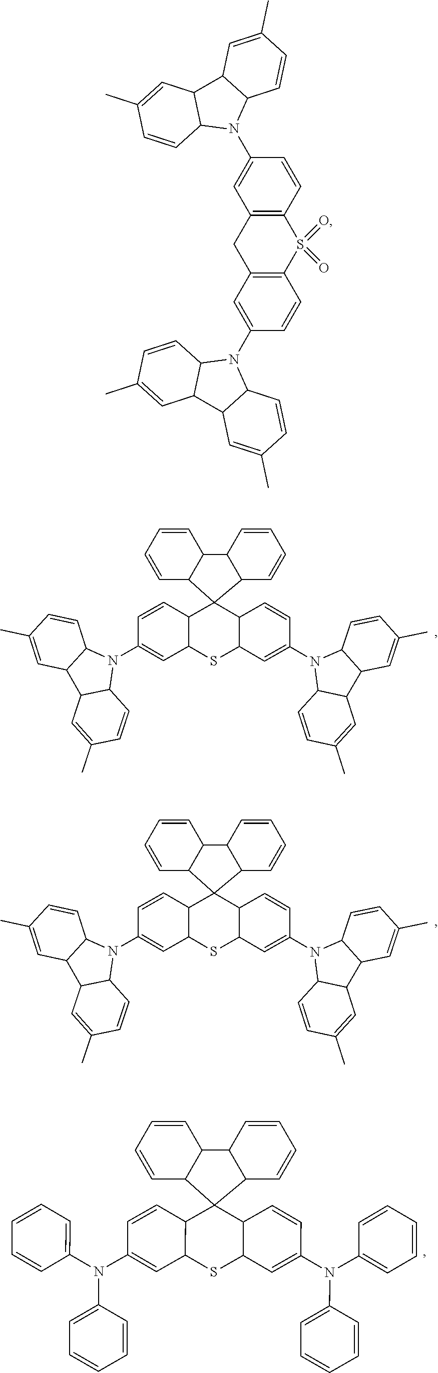

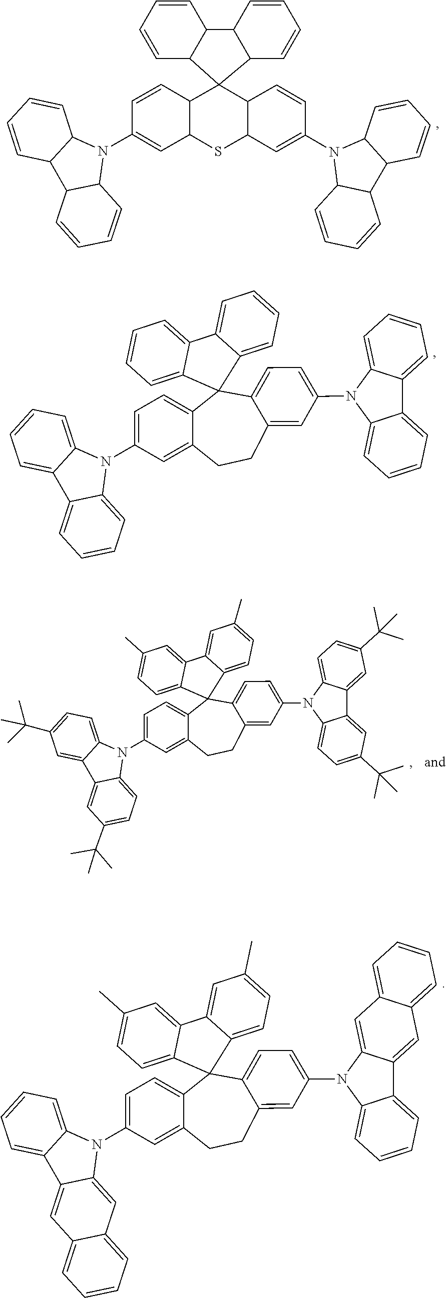 [SMILES: C1=CC2C3C=CC=CC3N(C3=CC4SC5C=C(N6C7C=CC=CC7C7C=CC=CC76)C=CC5C5(C4C=C3)C3C=CC=CC3C3C=CC=CC35)C2C=C1 ; c1ccc2c(c1)-c1ccccc1C21c2ccc(-n3c4ccccc4c4ccccc43)cc2CCc2cc(-n3c4ccccc4c4ccccc43)ccc21 ; Cc1ccc2c(c1)-c1cc(C)ccc1C21c2ccc(-n3c4ccc(C(C)(C)C)cc4c4cc(C(C)(C)C)ccc43)cc2CCc2cc(-n3c4ccc(C(C)(C)C)cc4c4cc(C(C)(C)C)ccc43)ccc21 ; Cc1ccc2c(c1)-c1cc(C)ccc1C21c2ccc(-n3c4ccccc4c4cc5ccccc5cc43)cc2CCc2cc(-n3c4ccccc4c4cc5ccccc5cc43)ccc21]

15. The light-emitting layer according to claim 1, wherein the light-emitting layer further comprises a second compound doped in the first thermally activated delayed fluorescent material; and
a triplet state energy level T1 of the first thermally activated delayed fluorescent material satisfies: T1≥2.7 eV.

16. The light-emitting layer according to claim 15, wherein the second compound is a third thermally activated delayed fluorescent material.

17. The light-emitting layer according to claim 15, wherein a general structure formula of the second compound is any one of: 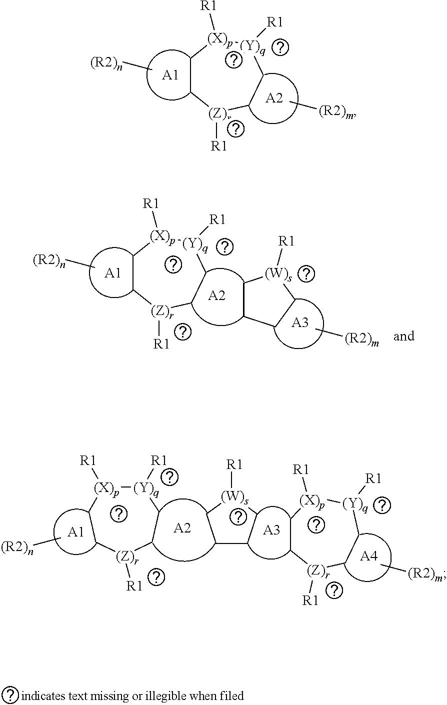
wherein X, Y, Z and W are each independently any one of carbon, nitrogen, boron, oxygen, sulfur, selenium, tellurium, BR3, C(R3)₂, —C(R3)₂—C(R3)₂—, —C(R3)₂—O—, —C(R3)₂—S—, —R3C═CR3-, —R3C═N—, Si(R3)₂, —Si(R3)₂—Si(R3)₂—, C═O, S═O, SO₂, NR3, PR3 and P(═O) R3;
R1 is any one of hydrogen, deuterium, fluorine, chlorine, bromine, iodine, CN, Si(R6)₃, a straight chain alkyl group, an alkoxyl group, a thioalkyl group with 1-40 carbon atoms, a branched chain with 3-40 carbon atoms, a cyclic alkyl group with 3-40 carbon atoms, an alkoxyl group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, a heteroaryloxy group with 5-60 aromatic rings, an arylalkyl group with 5-60 aromatic rings and a heteroarylalkyl group with 5-60 aromatic rings; R1 may be substituted with one or more R4, R4 is any one of hydrogen, a straight chain alkyl group with 1-22 carbon atoms, an alkoxyl chain with 1-22 carbon atoms, a branched chain with 3-22 carbon atoms, a cyclic alkyl group with 3-22 carbon atoms, and an alkoxy chain with 3-22 carbon atoms; one or more non-adjacent carbon atoms in R4 may be substituted with any one of oxygen, sulfur, SO, SO₂, CO, O—CO—O, CO—O, —CH═CH— and, —C≡C; one or more hydrogen atoms in R4 may be substituted with any one of fluorine, chlorine, bromine, iodine, CN, an aryl group with 5-40 carbon atoms, a heteroaryl group with 5-40 carbon atoms, an aryloxy group with 5-40 carbon atoms, a heteroaryloxy group with 5-40 carbon atoms and a non-aromatic group; one or more non-adjacent CH₂ in R1 may be substituted with any one of Si(R6)₂, C═NR6, P(═O)(R6), SO, SO₂, NR6, oxygen, sulfur, and CONR6; one or more hydrogen atoms in R1 may be substituted with any of deuterium, fluorine, chlorine, bromine and iodine;
two or more adjacent R1 form any one of a monocyclic aliphatic ring and a polycyclic aliphatic ring, which may be substituted with R4;
R2 is any one of hydrogen, deuterium, fluorine, chlorine, bromine, iodine, CN, Si(R6)₃, a straight chain alkyl group, an alkoxyl group, a thioalkyl group with 1-40 carbon atoms, a branched chain with 3-40 carbon atoms, a cyclic alkyl group with 3-40 carbon atoms, an alkoxyl group with 3-40 carbon atoms, a thioalkyl group with 3-40 carbon atoms, an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, a heteroaralkyl group with 5-60 aromatic rings, and a benzyl group with 10-30 aromatic rings; R2 may be substituted with one or more R4, R4 is any one of hydrogen, a straight chain alkyl group with 1-22 carbon atoms, an alkoxyl chain with 1-22 carbon atoms, a branched chain with 3-22 carbon atoms, a cyclic alkyl group with 3-22 carbon atoms, an alkoxy chain with 3-22 carbon atoms; one or more non-adjacent carbon atoms in R4 may be substituted with any one of oxygen, sulfur, SO, SO₂, CO, O—CO—O, CO—O, —CH═CH— and —C≡C; one or more hydrogen atoms in R4 may be substituted with any one of fluorine, chlorine, bromine, iodine, CN, an aryl group with 5-40 carbon atoms, a heteroaryl group with 5-40 carbon atoms, an aryloxy group with 5-40 carbon atoms, a heteroaryloxy group with 5-40 carbon atoms, and a non-aromatic group; one or more non-adjacent CH₂ in R1 may be substituted with any of Si(R6)₂, C═NR6, P(═O)(R6), SO, SO₂, NR6, oxygen, sulfur, and CONR6; one or more hydrogen atoms in R1 may be substituted with any of deuterium, fluorine, chlorine, bromine, and iodine;
one or more non-adjacent CH₂ in R2 may be substituted with any one of Si(R6)₂, C═NR6, P(═O)(R6), SO, SO₂, NR6, oxygen, sulfur, CONR6; and one or more hydrogen atoms in R2 may be substituted with any one of deuterium, fluorine, chlorine, bromine and iodine;
two or more adjacent R2 form any one of a monocyclic aliphatic ring and a polycyclic aliphatic ring, which may be substituted with R4;
A1, A2, A3 and A4 are each independently any one of an aromatic ring with 6-60 carbon atoms, a heteroaromatic ring with 6-60 carbon atoms, an aryloxy group with 5-60 aromatic rings, a heteroaryloxy group with 5-60 aromatic rings, an aralkyl group with 5-60 aromatic rings, and a heteroaralkyl group with 5-60 aromatic rings; and A1 and A2 may each independently substituted with one or more R4;
p, q, t and s are each independently 0 or 1, and p+q>0; and
m and n are each independently any one of 0, 1, 2, 3, or 4.

18. The light-emitting layer according to claim 17, wherein the second compound comprises at least one benzene ring, and a boron atom and/or a nitrogen atom.

19-21. (canceled)

22. A light-emitting device, comprising at least one of the light-emitting layer according to claim 1.

23. A display apparatus, comprising the light-emitting device according to claim 22.
